(19) United States
(12) Patent Application Publication
(10) Pub. No.: US 2025/0237673 A1
(43) Pub. Date: Jul. 24, 2025

(54) SYSTEM AND APPROVAL METHOD, INFORMATION ACQUISITION SYSTEM AND INFORMATION ACQUISITION METHOD, SHAPE ACQUISITION SYSTEM AND SHAPE ACQUISITION METHOD, AND MONITORING METHOD

(71) Applicant: NIKON CORPORATION, Tokyo (JP)

(72) Inventor: Takashi MIYAWAKI, Machida-shi (JP)

(73) Assignee: NIKON CORPORATION, Tokyo (JP)

(21) Appl. No.: 18/853,470

(22) PCT Filed: Apr. 3, 2023
(86) PCT No.: PCT/JP2023/013824

§ 371 Date: Oct. 2, 2024

(30) Foreign Application Priority Data
Apr. 4, 2022 (JP) 2022-062261
Sep. 5, 2022 (JP) 2022-140592

(51) Int. Cl. G01P 15/18; G06F 30/13

(52) U.S. Cl. CPC G01P 15/18; G06F 30/13

(57) ABSTRACT

A system includes a plurality of sensor devices, a server, and other terminal devices which are connected to each other via a network. The server issues a measurement instruction to the sensor devices measuring tilt information of a measurement target member in response to an inquiry for change in shape of the measurement target member from a predetermined terminal device, receives sensor data from the sensor devices, creates displaying data for displaying information related to shapes of the measurement target member in a current stage and a design stage on the basis of data of the shape of the measurement target member obtained from the sensor data and design data of the measurement target member, and transmits the displaying data to the terminal device of an inquiry source together with a display instruction command.

### TECHNICAL FIELD

The present invention relates to a system and an approval method, an information acquisition system and an information acquisition method, a shape acquisition system and a shape acquisition method, and a monitoring method, and more specifically relates to a system and a steel frame pillar erection approval method suitable for implementing approval for erection of a steel frame pillar, an information acquisition system and an information acquisition method for acquiring information related to a correspondence between each of a plurality of sensor devices and a measurement point thereof (a position where a sensor device is installed on an object), a shape acquisition system including the information acquisition system and a shape acquisition method for acquiring shape information of an object using a plurality of sensor devices which have acquired information related to a correspondence with respect to measurement points, and a method for monitoring change over time in shape of an object utilizing the shape acquisition method. The information acquisition method and the information acquisition system can also be favorably used for approval for erection and the like.

Priority is claimed on Japanese Patent Application No. 2022-062261, filed Apr. 4, 2022, and Japanese Patent Application No. 2022-140592, filed Sep. 5, 2022, the contents of which are incorporated herein by reference.

### BACKGROUND ART

In recent years, utilization of 3D models called building information modeling (BIM) has been increasing in the field of architecture. BIM is increasingly being utilized in design sites, that is, in planning, design planning, facility design, design analysis, detailed design, construction planning, and manufacturing of components. For example, Patent Document 1 discloses a technology utilizing BIM in scenes of manufacturing members in factories.

However, utilization of BIM at construction sites is lagging behind so that construction drawings are created independently based on design BIM created at design sites and construction is performed based on construction drawings. Construction drawings are created for each process, but since there is no system here for reflecting the actual construction status in upstream design BIM, construction drawings for the next process are created based on information of the old BIM. For this reason, emergence of a system enabling a construction status to be reflected in upstream drawings or passed on to a next construction process is desired.

In addition, for example, at construction sites of steel frame erection, approval work for erection of each steel frame is almost always performed through exchange of written documents between a workman and a manager, which requires manpower to create written documents and the like. In addition, in Japan, long working hours due to a labor shortage in the construction industry, which is also caused by the declining birthrate, aging population, and the like, are becoming a problem.

As a prerequisite for approval work for erection of a steel frame, erection measurement is essential. In order to efficiently perform this erection measurement, it is conceivable to perform erection measurement of a plurality of steel frames (pillars) in parallel using a plurality of measurement devices (for example, tilt detection means). However, when measurement of a plurality of objects is performed in parallel using a plurality of measurement devices, a technology with which each of the plurality of measurement devices is correctly and easily associated with each of the objects that are measurement targets is required.

### CITATION LIST

### Patent Document

Patent Document 1: Japanese Unexamined Patent Application, First Publication No. 2019-21190

### SUMMARY OF INVENTION

### Technical Problem

According to a first aspect of the present invention, there is provided a system including a plurality of sensor devices, a management device, and other terminal devices which are connected to each other via a network. Each of the plurality of sensor devices is attached to a member constituting infrastructure, a vehicle, or other moving objects, sets the member to which the sensor devices are individually attached as an object of measurement, individually measures tilt information of the object in response to a measurement instruction from the management device, and transmits sensor data including information of measurement results to the management device. The management device issues the measurement instruction to sensor devices measuring tilt information of the object in response to an inquiry for change in shape of the object from a predetermined terminal device connected via the network, receives sensor data from the sensor devices, creates displaying data for displaying information related to shapes of the object in a current stage and a design stage on the basis of data of the shapes of the object obtained from the sensor data and design data of the object included in a database storing design data of the object, and transmits the displaying data to the predetermined terminal device together with a display instruction command. The predetermined terminal device displays display contents corresponding to the displaying data on a display screen in response to the received display instruction command.

According to a second aspect of the present invention, there is provided a steel frame pillar erection approval method. The erection approval method includes issuing a creation instruction for an approval request screen including a designation of a target work area from a worker side terminal to a management device; causing the management device to acquire sensor data from sensor devices measuring tilt information of respective steel frame pillars which belong to the target work area in response to the issued creation instruction, obtain shapes of the respective steel frame pillars using the sensor data, obtain pillar head positions of the respective steel frame pillars from the obtained shapes, create displaying data of an approval request screen including positional deviation information of pillar heads of the respective steel frame pillars and approval request data linked to the positional deviation information on the basis of data of the pillar head positions and design data of the respective steel frame pillars, and transmit the created data to a manager side terminal; and causing the manager side terminal to receive displaying data of the approval request screen, and display an approval request screen on a display screen.

According to a third aspect of the present invention, there is provided an information acquisition system acquiring information related to a correspondence between each of a plurality of sensor devices attached at a plurality of different positions in an object and a measurement point thereof. The information acquisition system includes an acquisition device and a management device which are connected to each of the plurality of sensor devices via a network. Each of the plurality of sensor devices has a display device having a screen and a memory domain, and is capable of displaying data stored in the memory domain on the screen. The acquisition device is a portable terminal having a display. The acquisition device has a first function of displaying an acquisition screen for an identifier on a screen of the display, a second function of storing an identification number corresponding to the acquired identifier, a third function of displaying a registration screen for attachment position information on a screen of the display around when an acquisition screen for the identifier is displayed, and a fourth function of associating attachment position information input to the registration screen with the identification number and transmitting information of association results thereof to the management device. The management device acquires information related to a correspondence between the sensor devices and measurement points thereof on the basis of information of the received association results and management information including design information of attachment positions of the sensor devices.

According to a fourth aspect of the present invention, there is provided a shape acquisition system acquiring shape information of an object. The shape acquisition system includes the information acquisition system according to the third aspect, and the plurality of sensor devices which are individually connected to the information acquisition system via a network. The plurality of sensor devices are respectively attached at different positions in one or more of the objects when being used, and transmit sensor data including positional information acquired at respective attachment positions to the management device via the network. Each of the plurality of sensor devices outputs the sensor data at a timing set in advance or on the basis of an external command. In consideration of acquired information of the correspondence, the management device obtains shape information of the objects through computation using positional information included in the plurality of pieces of sensor data received via the network, and stores the obtained shape information in a storage.

According to a fifth aspect of the present invention, there is provided an information acquisition method for acquiring information related to a correspondence between each of a plurality of sensor devices attached at a plurality of different positions in an object and a measurement point thereof. The information acquisition method includes causing an acquisition device constituted of a portable terminal to display an acquisition screen for an identifier on a display screen, causing the acquisition device to acquire an identifier of each of the plurality of sensor devices, causing the acquisition device to display a registration screen for attachment position information on the display screen around when an acquisition screen for the identifier is displayed, causing the acquisition device to associate information input to the registration screen with an identification number corresponding to the acquired identifier, and transmit information of association results thereof to a management device, and causing the management device to acquire information related to a correspondence between sensor devices and measurement points thereof on the basis of information of the received association results and management information including design information of attachment positions of the sensor devices.

According to a sixth aspect of the present invention, there is provided a shape acquisition method for acquiring shape information of an object. The shape acquisition method includes causing a plurality of sensor devices, to which the information acquisition method according to the fifth aspect is applied and which are attached at a plurality of different positions in the object where information related to a correspondence with respect to each of measurement points is acquired by the management device, to individually acquire positional information of the object at a plurality of measurement points; and causing the management device, in consideration of information related to the acquired correspondence, to obtain shape information of the object through computation using the acquired positional information at the plurality of measurement points.

According to a seventh aspect of the present invention, there is provided a monitoring method including repeatedly executing the shape acquisition method according to the sixth aspect, and monitoring change over time in shape of the object on the basis of shape information obtained in every execution.

### BRIEF DESCRIPTION OF DRAWINGS

FIG. 1 A view schematically showing an overall constitution of a system according to a first embodiment.

FIG. 2 A block diagram showing a constitution of a sensor device.

FIG. 3 A perspective view showing an example of a steel frame building constituted to include steel frame pillars that are measurement targets of the sensor devices.

FIG. 4 A view showing an example in which the sensor devices are attached to a steel frame pillar at the same height positions on two surfaces extending in a longitudinal direction and orthogonal to each other.

FIG. 5 An explanatory view for the meaning of tilt angles output from the sensor devices (angle sensors).

FIG. 6 An explanatory view of a method for calculating a shape of a measurement surface (first surface) of a pillar 100₁ to which sensor devices 18₁ to 18₃ are attached.

FIG. 7 A flowchart showing a processing algorithm which is related to approval work for erection of a steel frame and executed in accordance with a program by a CPU of a mobile terminal.

FIG. 8 Part (A) is a view showing an example of a registration screen for an approval request target work area in a state in which pull-down menus of all items are closed, and part (B) is a view showing an example of a screen after selection when a workman has opened all the pull-down menus and made necessary selections.

FIG. 9 A flowchart showing a processing algorithm which is related to approval work for erection of a steel frame and executed in accordance with a program by a CPU of a server.

FIG. 10 A flowchart showing a processing algorithm which is executed by the CPU of the server in accordance with a program concomitantly with approval work for erection of a steel frame.

FIG. 11 A flowchart showing a processing algorithm which is related to approval work for erection of a steel frame and executed in accordance with a program by a CPU of a work site side computer.

FIG. 12 A view showing an example of an approval request screen displayed on a display screen of the work site side computer.

FIG. 13 A view showing the approval request screen in FIG. 12 after an end button has been selected subsequently to selection of a necessary approval button.

FIG. 14 A view showing another example of the approval request screen displayed on the display screen of the work site side computer.

FIG. 15 A view showing the approval request screen in FIG. 14 after the end button has been selected subsequently to selection of all the approval buttons.

FIG. 16 A flowchart showing a control algorithm which is executed in accordance with a program by the CPU of the server in regard to creation of 3D image data visually showing a tilt state of a steel frame.

FIG. 17 A view showing an example of an image three-dimensionally displaying the tilt states of steel frames displayed on a display screen of a terminal device.

FIG. 18 A flowchart showing a processing algorithm which is executed in accordance with a program by a CPU of a server 12 in a system according to a second embodiment.

FIG. 19 A view showing an example of a display screen for a positional deviation which belongs to a designated work area displayed on a display screen of the mobile terminal as a result of processing of the server in accordance with the flowchart in FIG. 18.

FIG. 20 A flowchart showing a processing algorithm which is executed in accordance with a program by the CPU of the server 12 in a system according to a third embodiment.

FIG. 21 A view schematically showing an overall constitution of a shape acquisition system according to a fourth embodiment.

FIG. 22 A block diagram showing an example of a constitution of a sensor device used in the system in FIG. 21.

FIG. 23 A perspective view schematically showing the appearance of the sensor device used in the system in FIG. 21.

FIG. 24 Part (A) is a view showing a pillar which has been delivered, part (B) is a view showing a state in which a predetermined number of sensor devices are attached to the pillar, and part (C) is a view showing a situation in which QR codes (registered trademark) displayed in the sensor devices are read by the mobile terminal.

FIG. 25 A flowchart showing a flow of processing of an information acquisition method according to the fourth embodiment.

FIG. 26 A flowchart corresponding to a processing algorithm of the CPU of the mobile terminal during execution of the information acquisition method according to the fourth embodiment.

FIG. 27 Part (A) is a view showing an example of an attachment position registration screen displayed on a screen of the mobile terminal, and part (B) is a view showing an example of a screen after selection of each of the items has ended.

FIG. 28 A flowchart showing a processing algorithm of a routine of interruption processing executed by the CPU of the server.

FIG. 29 A flowchart showing a flow of a shape acquisition method according to the fourth embodiment.

FIG. 30 A flowchart showing a processing algorithm which is executed by a CPU of a computation processing unit of the sensor device.

FIG. 31 A flowchart showing a measurement processing algorithm according to a measurement processing program which is executed by the CPU of the server.

FIG. 32 A flowchart corresponding to a processing algorithm of the CPU of the mobile terminal according to a modification example.

FIG. 33 A flowchart showing a flow of processing of an information acquisition method according to a fifth embodiment.

FIG. 34 Part (A) is a view showing a situation in which a plurality of sensor devices are taken out from a box and placed side by side on a floor surface, and part (B) is a view showing a situation in which the QR codes displayed in the sensor devices are read by the mobile terminal.

FIG. 35 A view showing a display example of attachment position identification data displayed on a display panel of the sensor device.

FIG. 36 A flowchart corresponding to a processing algorithm of the CPU of the mobile terminal during execution of the information acquisition method according to the fifth embodiment.

FIG. 37 A view schematically showing an example of a business model when the server is a cloud and is under management of a supplying company of the sensor devices.

### DESCRIPTION OF EMBODIMENTS

### First Embodiment

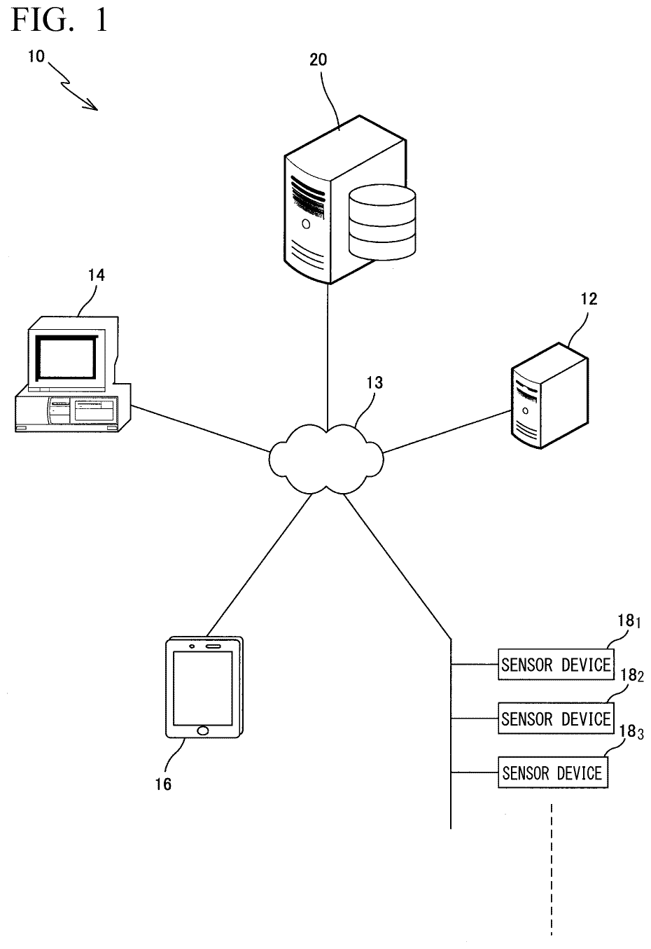

Hereinafter, a first embodiment will be described on the basis of FIGS. 1 to 17.

FIG. 1 schematically shows an overall constitution of a system 10 according to the first embodiment suitable for performing a steel frame pillar erection approval method.

The system 10 is constituted to include a server 12 that also functions as a management device, a work site side computer 14 that serves as a manager side terminal, a mobile terminal 16 that serves as a worker side terminal, a plurality of sensor devices 18ᵢ (i=1, 2, 3, and so on), and a database server 20, which are connected to each other via a wide area network (which will hereinafter be suitably abbreviated to a network) 13 such as the Internet.

The plurality of sensor devices 18ᵢ are connected to the network 13 via communication lines, for example, a wireless LAN. In FIG. 1, three sensor devices 18₁ to 18₃ of the plurality of sensor devices 18ᵢ are representatively shown. All the communication lines may be wireless, but at least some may be wired. The present embodiment employs a constitution in which outputs of the plurality of sensor devices 18ᵢ are directly provided to the server 12 via the communication lines and the network 13. However, it is not limited to this, and a constitution in which outputs of the sensor devices 18ᵢ are provided to the server 12 via the work site side computer 14 may be adopted. The communication lines and the network 13 may be a part of the same network. Hereinafter, one network constituted to include the network 13 and all the communication lines connecting the server 12, the work site side computer 14, the mobile terminal 16, the plurality of sensor devices 18ᵢ, and the database server 20 to the network 13 will be indicated as the network 13 using the same reference sign as the wide area network 13.

In the present embodiment, a generally used server computer is used as the server 12, but a cloud (computer) may be used. The server 12 includes a CPU, a ROM, a RAM, a HDD, and the like (storage), which are not shown in the diagrams, and the CPU utilizes the RAM as a work domain, for example, and executes various processing algorithms stipulated by various programs stored in the ROM, the HDD, and the like. The constitution of the server 12 which also functions as a management device is not limited to that in the present embodiment. In addition, the management device is not limited to hardware as in the present embodiment and may be software capable of executing at least a computation function, for example.

In the present embodiment, a generally used computer is used as the work site side computer 14. The work site side computer 14 includes operation units such as a keyboard and a mouse, and a display unit such as a liquid crystal display. The work site side computer 14 performs data communication with other terminal devices (the server 12, the mobile terminal 16, the database server 20, and the like) connected to the network 13 via the network 13 in response to an instruction input by a work site supervisor or other managers via the operation units. In the present embodiment, as will be described below, since approval is performed by an approver (for example, a work site manager) having approval authority, it is better to provide a manager side terminal separately from the worker side terminal. However, the work site side computer 14 does not necessarily have to be provided as the manager side terminal, and a mobile terminal similar to the mobile terminal 16 may be provided.

The mobile terminal 16 is carried by a workman at a construction site (which will hereinafter be suitably referred to as an on-site workman, a workman, or a worker). As an example, a smartphone is used as the mobile terminal 16. The mobile terminal may be a generally used portable computer, for example, a tablet PC.

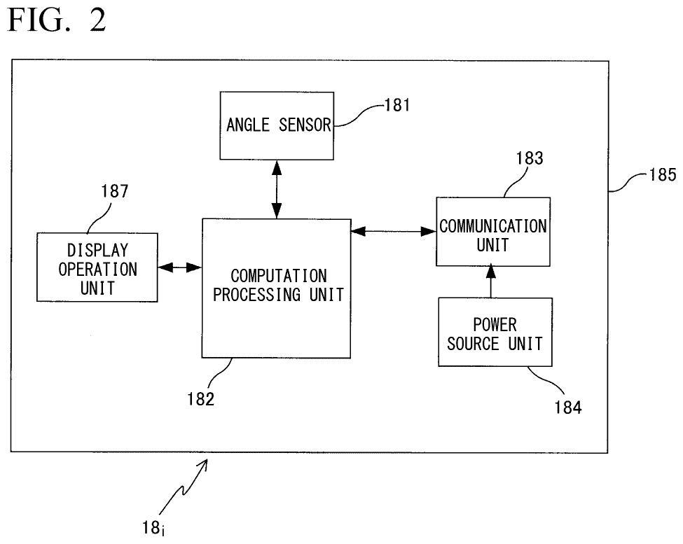

As shown in FIG. 2, each of the sensor devices 18₁ includes an angle sensor 18₁, a computation processing unit 182, a communication unit 183, a power source unit 184 (constituted of a battery, for example), a display operation unit 187, and a waterproof casing 185 which internally accommodates these. The power source unit 184 has a constitution in which power supply to each unit can be turned on and off by a remote operation from the outside (for example, the server 12, the work site side computer 14, the mobile terminal 16, or the like). Without being limited to this, a power source switch which can be manually turned on and off may be provided in the casing 185.

In addition, the sensor devices 18ᵢ are not limited to the constitution of the present embodiment, and all the angle sensor 181, the communication unit 183, and the like may not be integrally constituted. In the present embodiment, the sensor devices 18ᵢ need only include the angle sensor 181, and the angle sensor 181 may be connected to other units (including the computation processing unit 182 and the like) through wireless or wired communication lines and may be constituted such that data is output from the angle sensor 181 via the communication lines and power is supplied to the angle sensor 181.

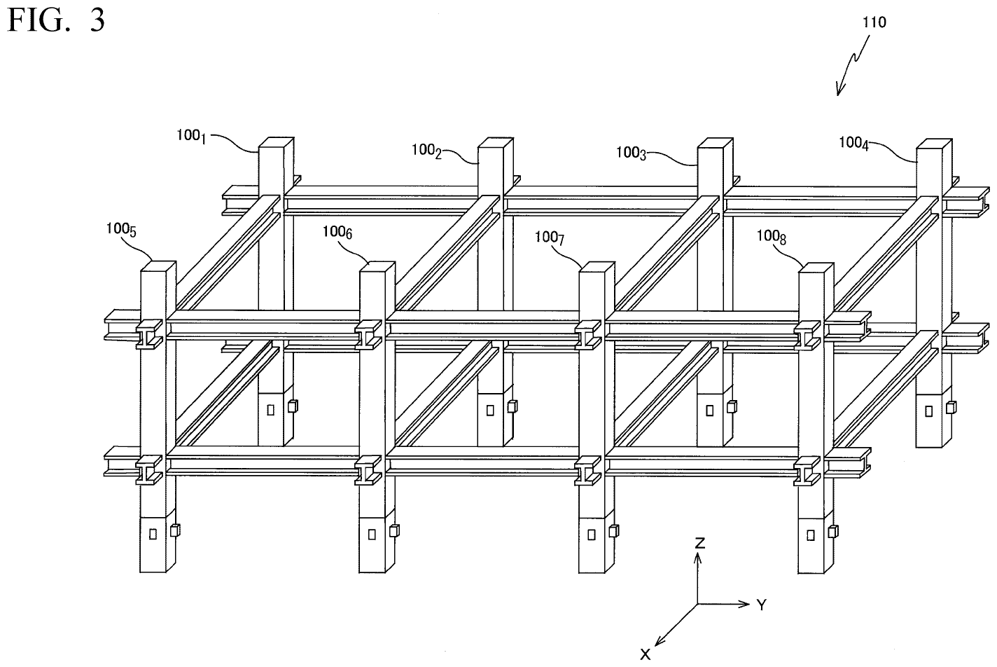

The sensor devices 18ᵢ respectively have, as a measurement target, steel frame pillars (which will hereinafter be suitably referred to as steel frames) 100ⱼ (j=1, 2, 3, and so on) constituting a steel frame building 110 shown in FIG. 3. Hereinafter, as shown in FIG. 3, a vertical direction (direction of gravity) will be regarded as a Z axis direction, a lateral direction within the paper in FIG. 3 within a plane orthogonal to the Z axis will be regarded as a Y axis direction, a direction orthogonal to the Z axis and the Y axis will be regarded as an X axis direction, and tilt (rotation) directions around the X axis, the Y axis, and the Z axis will be respectively regarded as θx, θy, and θz directions in the description.

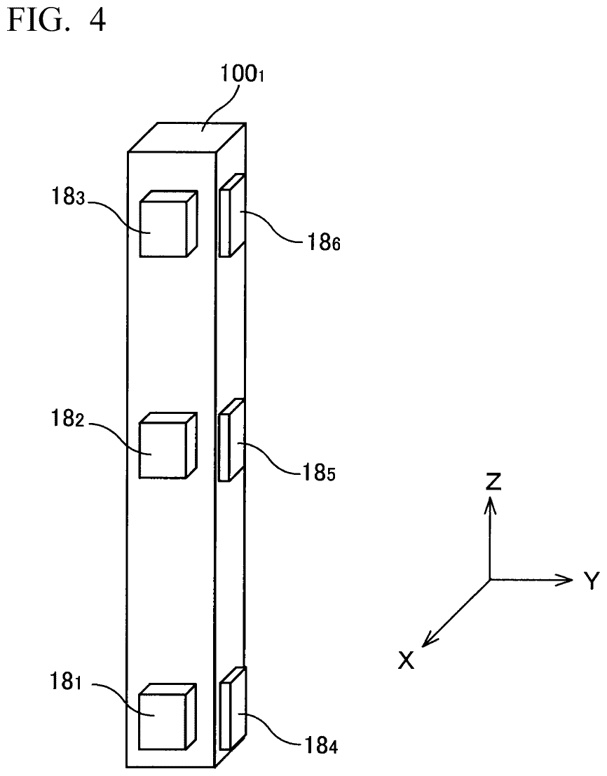

As shown in FIG. 4 taking a steel frame 100ᵢ as an example, a total of six sensor devices 18ᵢ are attached to one steel frame. In the steel frame 100₁, the sensor devices 18₁, 18₂, and 18₃ are attached to a surface on the positive X side, and the sensor devices 18₄, 18₅, and 18₆ are attached to a surface on the positive Y side. The sensor devices 18₁ and 18₄ are attached at the same height positions in a pillar leg portion, and the sensor devices 18₃ and 18₆ are attached at the same height positions in a pillar head portion. In addition, the sensor devices 18₂ and 18₅ are attached at the same height positions in a part between the pillar leg and the pillar head. The position of an attachment position of each of the sensor devices 18ᵢ in the Z axis direction, that is, the distance from the upper end (or the lower end) is already known. Six sensor devices 18ᵢ are also attached to other steel frames 100₂ to 100₈ in a similar disposition. Here, the relationship between the attachment position (which position from the bottom in which steel frame) of each of the sensor devices 18ᵢ and the sensor number (identification number unique to the sensor device) is managed by the server 12. In addition, the attachment position of each of the sensor devices 18₁, that is, position coordinates (X, Y, Z) of a measurement point of each of the sensor devices 18ᵢ is managed by the server 12. That is, each of the sensor devices 18ᵢ is attached at a position set by the server 12.

The sensor devices 18ᵢ are attached to the steel frame pillar 100ⱼ utilizing magnetic forces of a plurality of permanent magnets (not shown), as an example. The sensor devices do not necessarily need to be attached utilizing a magnetic force, and bolt fastening or other fixing methods may be used.

Returning to the description of FIG. 2, in the present embodiment, as an example, a three-dimensional microelectromechanical system (3D MEMS) tilt angle sensor is used as the angle sensor 181. The 3D MEMS tilt angle sensor is a precision tilt sensor produced using 3D MEMS technology. Extremely little power is required for the 3D MEMS tilt angle sensor, which is a power consumption in a microampere range and this is suitable for wireless application. An angle sensor, into which two MEMS acceleration sensors having symmetrical output characteristics and an ASIC are built, is used as the angle sensor 181 and outputs information of tilt angles (α, β, and γ) (tilt information) in three directions (θx direction, θy direction, and θz direction), for example. The angle sensor is not limited to a 3D MEMS tilt angle sensor, and other kinds of three-dimensional tilt angle sensors may be used. In addition, the angle sensor is not limited to a three-dimensional tilt angle sensor, and a two-dimensional tilt angle sensor or a one-dimensional tilt angle sensor may be used depending on the measurement object. At this time, a two-dimensional tilt angle sensor and a one-dimensional tilt angle sensor may be used in combination, or a plurality of two-dimensional tilt angle sensors or one-dimensional tilt angle sensors may be used in combination.

For example, the computation processing unit 182 is constituted of a microcontroller unit (MCU) and has a CPU (not shown), a memory device (memory), an input/output circuit, and a timer circuit. The computation processing unit 182 executes a processing algorithm stipulated by a program stored in the memory device. The computation processing unit 182 links identification information (ID) of the sensor devices 18ᵢ to data including information of the tilt angle (tilt information) output from the angle sensor 181 and outputs it to the communication unit 183 as one piece of sensor data. The computation processing unit 182 also controls the entire sensor devices 18ᵢ. The ASIC built into the angle sensor 181 may have the function of the computation processing unit 182 without providing the computation processing unit 182.

In the present embodiment, the communication unit 183 functions as a Wi-Fi communication (wireless LAN communication) unit. The sensor devices 18ᵢ can perform wireless LAN communication with the server 12 and other instruments connected to the network 13 via the network 13. The sensor data described above is output from the communication unit 183 to the server 12 via the network 13. A part of the communication unit 183 may be constituted of a wired communication unit.

For example, the display operation unit 187 can be constituted of a small-sized touch panel. The touch panel is an electronic component, in which a display device such as a liquid crystal panel and a position input device such as a touch pad are combined, and is an input device for operating instruments by tapping on the display on a screen. The sensor devices 18ᵢ may include a temperature/humidity sensor, an impact sensor, and the like, for example, in addition to the angle sensor 181. For example, the display operation unit 187 is used when a worker inputs identification information (ID) of the sensor devices during initial setting of the sensor devices 18. Initial setting is performed by a worker when the sensor devices 18ᵢ are attached to an object. Here, an input ID includes information indicating the sensor number and the attachment position of the sensor device. An input ID is stored in the memory (for example, the RAM) by the computation processing unit 182 and is included in the sensor data as described above. All the initial setting work of the sensor devices 18ᵢ including an input of identification information (ID) and the like does not necessarily have to be performed by a workman, and the server 12 may perform at least a part of the initial setting work, for example. In this case, in a stage in which attachment of each of the plurality of sensor devices 18ᵢ is completed, the sensor devices 18ᵢ may notify the server 12 of completion of attachment, the server 12 may set identification information and the like. For example, in a stage in which attachment of the sensor devices 18 is completed, a worker turns on power sources of the sensor devices 18ᵢ of which attachment has been completed via the mobile terminal 16 (or when a power source switch is provided, by operating the power source switch). Further, by turning on these power sources, commands for informing of completion of attachment can be transmitted from the sensor devices 18ᵢ to the server 12 together with the sensor numbers. The server 12 which has received these commands completes the initial setting of the sensor devices 18ᵢ that are command transmission sources.

Returning to the description of FIG. 1, the database server 20 includes a database storing design data of the steel frame building 110 (refer to FIG. 3). A database server denotes a server in which a database management system (DBMS) operates in a hierarchical system having a plurality of servers sharing roles. The software operates in a server computer which is constituted of a main body of the database management system (DBMS), an interface for connection and operation from the outside, a program for data management, and the like and has a large-capacity storage device that is built into or connected to the server computer. The database server 20 performs operations such as recording, rewriting, and deleting data with respect to the storage via the DBMS, and searching and returning data in accordance with the conditions. However, hereinafter, description related to the interface, the DBMS, and the like will be omitted, and it will be expressed as accessing the database server 20 from an external terminal device (for example, the server 12 or the like), reading data from the database, or writing data in the database. Design data stored in the database includes design data regarding structural materials, for example, steel frame pillar. Here, the design data is 3D data, but it may not be 3D data. The database server may be a cloud.

In the present embodiment, the shape of a first surface (surface on the positive X side) of the steel frame 100₁ can be obtained on the basis of outputs of the sensor devices 18₁, 18₂, and 18₃, and the shape information of a second surface (surface on the positive Y side) can be obtained on the basis of outputs of the sensor devices 18₄, 18₅, and 18₆.

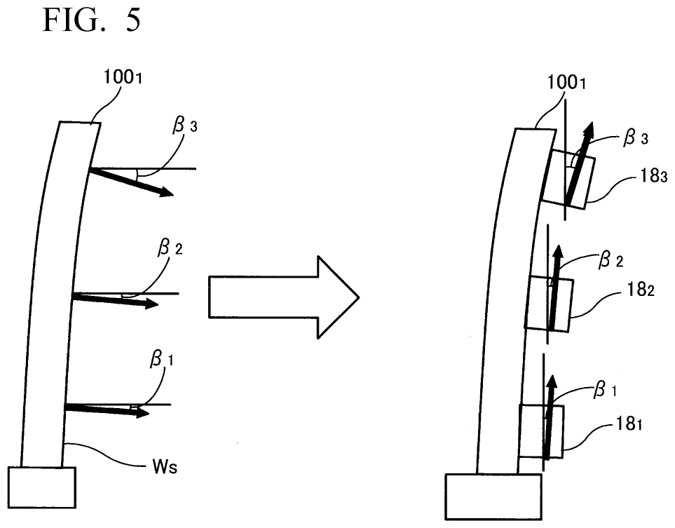

Here, as an example, a case of calculating the shape within an XZ plane on the first surface (which will hereinafter be indicated as a measurement surface Ws) where the sensor devices 18₁ to 18₃ of the pillar 100₁ are attached will be simply described. Here, the shape within the XZ plane is taken in the pillar 100₁ because the three sensor devices 18₁ to 18₃ are disposed in an upward-downward direction on the measurement surface Ws. Since the sensor devices 18ᵢ each include the angle sensor 18₁ constituted of a three-dimensional MEMS sensor, a tilt angle βᵢ of a normal vector at each of the measurement points (measuring points) on the measurement surface Ws shown on the left side in FIG. 5 is output as the tilt of the sensor device 18ᵢ (angle based on the axis in the direction of gravity) as shown on the right side in FIG. 5. Therefore, there is no need to set references for measurement and the like by a three-dimensional surveying instrument in the related art.

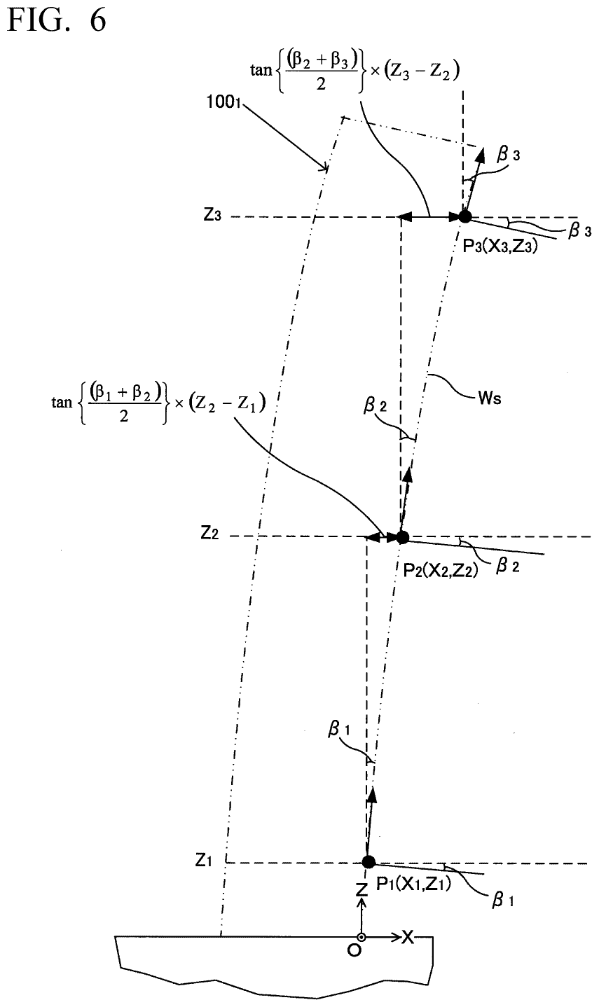

As shown in FIG. 6, when the sensor devices 18₁, 18₂, and 18₃ are respectively indicated as points P₁, P₂, P₃, and positions on the measurement surface Ws where the sensor devices 18₁, 18₂, and 18₃ are attached are respectively P₁(X₁,Z₁), P₂ (X₂,Z₂), and P₃ (X₃,Z₃), an X position X₂ of the point P₂ and an X position X₃ of the point P₃ can be obtained as follows through calculation. It is assumed that the origin of the XZ coordinate system is set at a lower end point on the measurement surface Ws of which the shape is to be obtained.

$${X}_{2} = {X}_{1} + tan \{ ( {β}_{1} + {β}_{2} ) / 2 \} \times ( {Z}_{2} - {Z}_{1} ) \qquad ( 1 )$$

$${X}_{3} = {X}_{2} + tan \{ ( {β}_{2} + {β}_{3} ) / 2 \} \times ( {Z}_{3} - {Z}_{2} ) \qquad ( 2 )$$

However, in FIG. 6 (and FIG. 5), in order to make the description easier to visually understand, a tilt angle β₁ measured by the sensor device 18₁ is shown particularly larger than it actually is. Actually, since the tilt angle β₁ is a very small angle, an X position X₁ of the point P₁ becomes X₁≈Z₁ tan β₁≈0, and X₂ can be calculated from the known values Z₂, Z₁, β₁, and β₂ by substituting this into Expression (1). Moreover, X₃ can be calculated from the known values X₂, Z₂, Z₃, β₂, and β₃ by substituting the obtained X₂ into Expression (2).

Next, the shape within the XZ plane (the shape of the XZ cross section) on the measurement surface Ws can be obtained by fitting the obtained points P₁(X₁,Z₁), P₂(X₂,Z₂), and P₃(X₃,Z₃) using a suitable function.

Similar to the first surface, the shape within a YZ plane on the second surface of the steel frame 100₁ can be obtained. In addition, the shapes of the first surface and the second surface which are orthogonal to each other can also be obtained for the steel frames 100ⱼ (j=2, 3, and so on) other than the steel frame 100₁.

Here, since each of the sensor devices outputs a three-dimensional tilt angle, it is also theoretically possible to obtain the shape of the second surface simply by mounting the sensor devices 18₁, 18₂, and 18₃ on the first surface. However, actually, since a rotation error may occur in the sensor device around the normal vector on the attachment surface during attachment, when it is desired to know the shape of the first surface and the shape of the second surface, it is better to mount sensor devices on both surfaces. In addition, while having measurement results of the first surface and the second surface by a known surveying instrument as initial values, fluctuation from the results may be continuously measured with sensors attached to the first surface, and the measured fluctuation can also be adopted as fluctuation results of the first surface and the second surface. At this time, measurement information (measured information) of the surveying instrument and measurement information of the sensor devices are associated. However, for example, association may be performed using measurement values themselves, or association may be performed using approximation curves indicating a tilt of the steel frame. When association is performed using approximation curves, an approximation function x=f(z) indicating the shape of the first surface and an approximation function y=g(z) indicating the shape of the second surface are obtained by measuring positional information at a plurality of points on each of the first surface and the second surface and performing fitting using a suitable function as described above. Meanwhile, the measurement values of the tilt angles (β and α) are acquired by measuring the tilt angles in the θy direction and the θx direction using each of the plurality of (here, three) sensor devices 18ᵢ attached to the first surface. Further, a calculation value of the tilt angle β at each of the measurement points is obtained by obtaining a function x=f′(z) in which the approximation function x=f(z) is differentiated with z and substituting Z coordinate values at the attachment positions (measurement points) of the three sensor devices attached to the first surface into the function x=f′(z). Further, relationships between both are obtained from the measurement values of the tilt angle β at the measurement points measured by the respective sensor devices 18ᵢ and the calculation values of the tilt angle β at the same measurement points (Z positions). The measurement information on the first surface by the surveying instrument and the measurement information of the sensor devices can be associated by obtaining these relationships. Similarly, a calculation value of the tilt angle α at each of the measurement points is obtained by obtaining a function y=g′(z) in which the approximation function y=g(z) is differentiated with z and substituting the Z coordinate values at the attachment positions (measurement points) of the three sensor devices attached to the first surface into the function y=g′(z). Further, relationships between both are obtained from the measurement values of the tilt angle α measured by the respective sensor devices 18ᵢ and the corresponding to calculation values of the tilt angle α at the same Z positions. The measurement information on the second surface by the surveying instrument and the measurement information of the sensor devices can be associated by obtaining these relationships. Those which have been described here can also be applied to second and third embodiments which will be described below.

Next, approval work for erection of a steel frame performed using the system 10 according to the present embodiment will be described. Concurrently, functions of each constituent part of the system 10 will also be described.

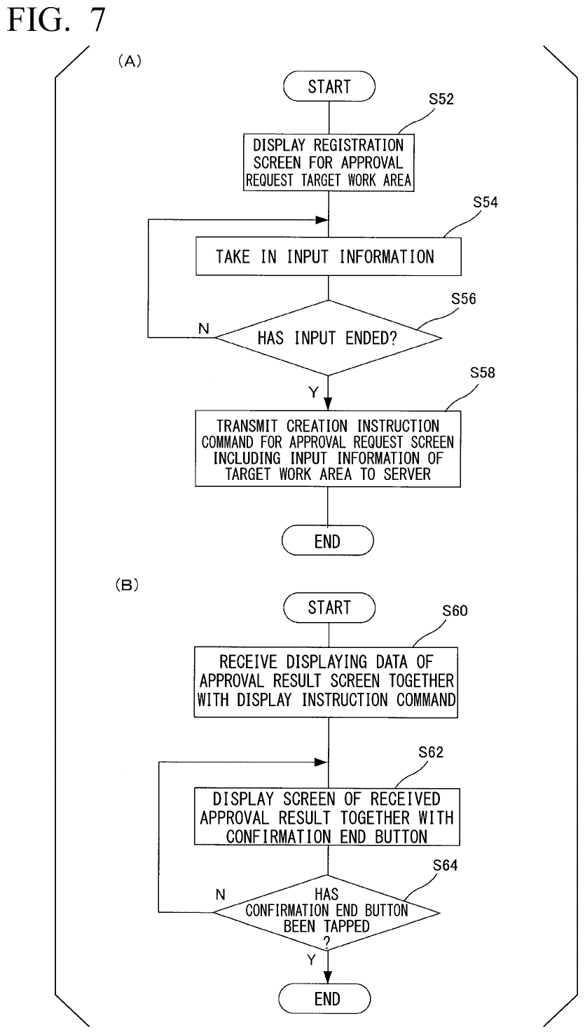

FIGS. 7(A) and 7(B) each shows a flowchart corresponding to a processing algorithm which is related to approval work for erection of a steel frame and executed in accordance with a program by the CPU of the mobile terminal 16. Applications (programs) corresponding to these processing algorithms are installed in advance in the mobile terminal 16.

The flowchart in FIG. 7(A) starts with activation of the application.

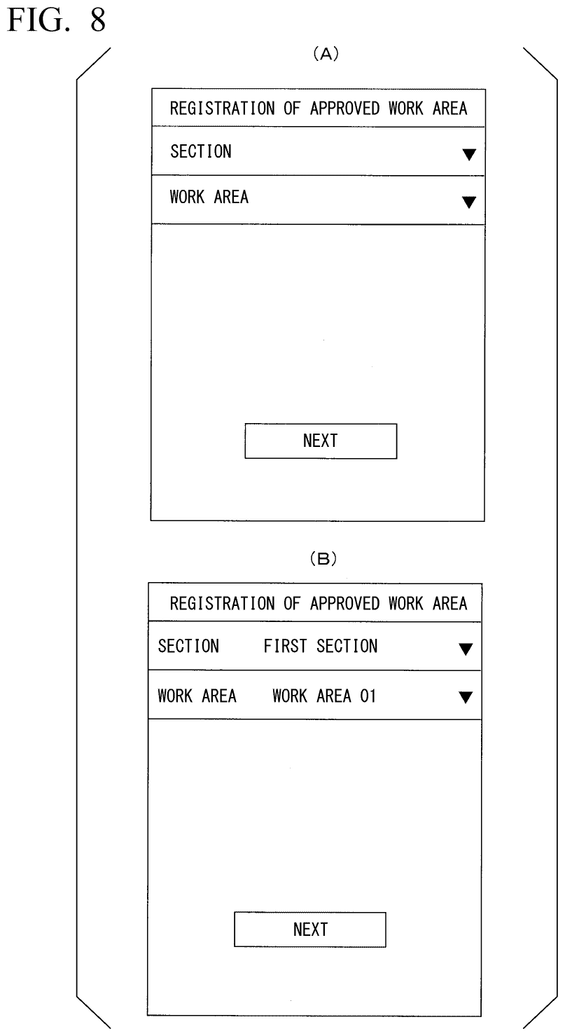

First, in Step S52, a display screen displays a registration screen for an approval request target work area. FIG. 8(A) shows an example of this registration screen. This registration screen of FIG. 8(A) displays a button “NEXT” together with a selection screen for a pull-down menu of items which will be described subsequently.

In FIG. 8(A), if the mark “▾” on the right side of the item “SECTION” is tapped, for example, the pull-down menu of “SECTION” in which choices for the section number such as a first section, a second section, and a third section are enumerated opens. If the mark “▾” on the right side of the item “WORK AREA” is tapped, for example, the pull-down menu of “WORK AREA” in which choices for the work area number such as a work area 01 and a work area 02 are enumerated opens.

FIG. 8(B) shows an example of a screen after selection when an on-site workman has opened all the pull-down menus and made necessary selections.

As is clear from the foregoing description, an input with respect to the registration screen is performed simply through selection work.

Returning to the description of FIG. 7(A), in the loop of Steps S54 to S56, the information input through selection of a workman is sequentially stored in the memory (RAM) until the button “NEXT” is tapped (inputting ends). Further, if the workman ends necessary selection work with respect to the foregoing registration screen and taps the button “NEXT”, the judgment in Step S56 becomes positive, and the processing proceeds to Step S58.

In Step S58, after a creation instruction command for an approval request screen including information of a target work area input by the workman is transmitted to the server 12, the processing ends. Here, transmission is performed after communication with the server 12 is established in a predetermined procedure. As will be described below, since change in shape of a steel frame pillar which belongs to a target work area (that is, the measurement targets of the sensor devices 18ᵢ) is obtained as a prerequisite for creation of the approval request screen, transmission of a creation instruction command for an approval request screen to the server 12 also serves as an inquiry for change in shape of a member (steel frame pillar) that is the measurement targets of the sensor devices 18ᵢ from the mobile terminal 16 to the server 12. The flowchart in FIG. 7(B) will be described below.

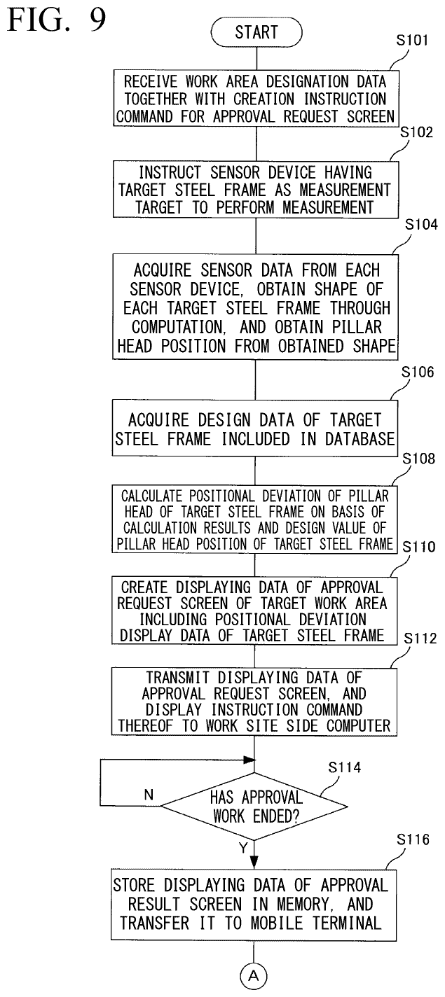

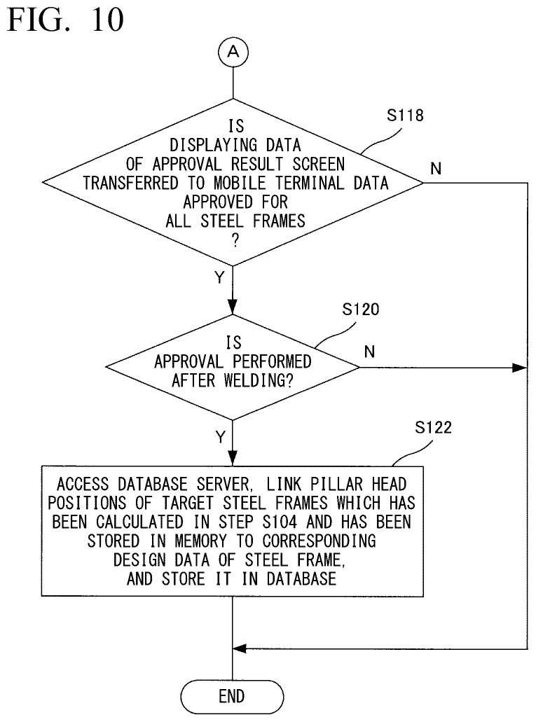

FIG. 9 shows a flowchart corresponding to a processing algorithm which is related to approval work for erection of a steel frame and executed in accordance with a program by the CPU of the server 12, and FIG. 10 shows a flowchart corresponding to a processing algorithm which is executed by the CPU of the server in accordance with a program concomitantly with approval work for erection of a steel frame. The programs corresponding to the processing algorithms in FIGS. 9 and 10 are installed in advance in the server 12.

The flowchart in FIG. 9 starts when communication between the mobile terminal 16 and the server 12 is established during transmission of a creation instruction for an approval request screen in Step S58 described above.

Here, communication for transmission of a creation instruction for an approval request screen between the mobile terminal 16 and the server 12 is established when a workman desires to receive approval for erection accuracy of a steel frame from an approver (a manager or the like), specifically when rebuilding of a steel frame has ended, when bolt tightening of pillar couplers has ended, when welding of a steel frame has ended, or the like, and erection measurement of the steel frame (pillar) is performed in any event.

As described above, a creation instruction for an approval request screen includes a designation of a target work area (here, a target section (the first section, the second section, and so on) and a work area (the work area 01, the work area 02, and so on)).

First, in Step S101, a creation instruction command for an approval request screen and work area designation data are received.

In the following Step S102, the sensor devices 18ᵢ having each steel frame pillar (steel frame) which belongs to a designated work area of a designated section (which will hereinafter be suitably referred to as a target work area) as a measurement target are instructed to perform measurement. Hereinafter, a steel frame which belongs to a target work area will also be referred to as a target steel frame.

In response to a measurement instruction, measurement is performed by the sensor devices 18ᵢ having each target steel frame as a measurement target, and the sensor data is output to the server 12. For example, when a creation instruction for an approval request screen includes a designation of the work area 01 of the first section, the tilt information of the steel frames 100₁ to 100₈ shown in FIG. 3 is measured by the sensor devices 18ᵢ (i=1 to 48) at each of the measurement points, and the sensor data is output to the server 12 from these sensor devices 18₁ to 18₄₈.

In Step S104, the sensor data is acquired from each of the sensor devices 18ᵢ which have been instructed to perform measurement, the shape of each target steel frame is obtained through computation, and the pillar head position (X, Y) is obtained from the obtained shape. Specifically, (functions indicating) the shapes of the first surface and the second surface of each target steel frame are obtained by the method as described earlier in the case in which the steel frame 100₁ is taken and the first surface (measurement surface Ws) is obtained, and the pillar head position (X, Y) is obtained from the obtained shapes of the first surface and the second surface. In this case, the X position of the pillar head is obtained from the shape of the first surface, and the Y position of the pillar head is obtained from the shape of the second surface, respectively. The information obtained in Step S104 is stored in the memory.

In the following Step S106, the database server 20 is accessed, and the design data of the target steel frame included in the database is acquired.

In the following Step S108, positional deviation information of the pillar head of the target steel frame is calculated on the basis of calculation results and design data (design value) of the pillar head position of the target steel frame.

Next, in Step S110, displaying data of the approval request screen of the target work area (designated work area) including positional deviation display data of the target steel frame is created.

In the following Step S112, the displaying data of the approval request screen and a display instruction command thereof are transmitted to the work site side computer 14. The displaying data of the approval request screen and the like are transmitted after communication with the work site side computer 14 is established in accordance with a predetermined procedure.

Thereafter, the processing proceeds to Step S114 and waits until approval work ends.

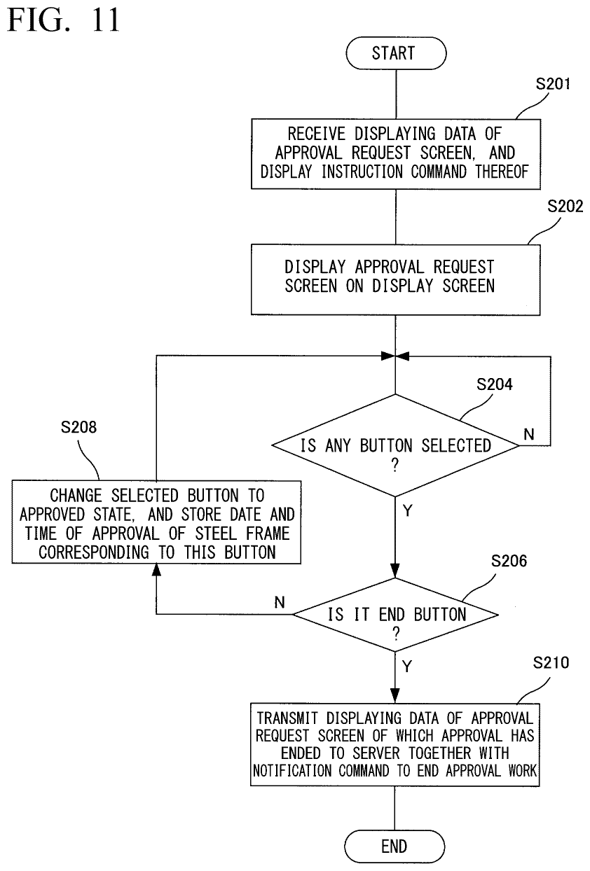

FIG. 11 shows a flowchart corresponding to a processing algorithm which is related to approval work for erection and executed in accordance with a program by the CPU of the work site side computer 14. A program corresponding to the processing algorithm in FIG. 11 is installed in advance in the work site side computer 14.

The flowchart shown in FIG. 11 starts when communication has been established during transmission of the displaying data of the approval request screen and the like in Step S112 described above.

First, in Step S201, the displaying data of the approval request screen and a display instruction command thereof are received.

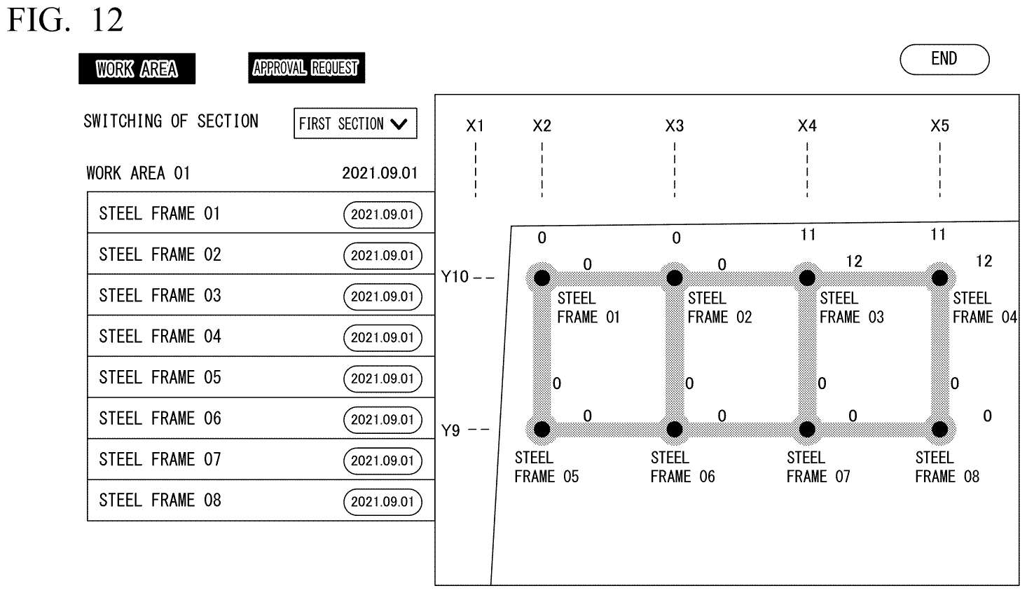

In the following Step S202, the approval request screen is displayed on the display screen in compliance with a display instruction command. As an example, the approval request screen shown in FIG. 12 is displayed on the display screen of the work site side computer 14. This screen shown in FIG. 12 is an example showing an approval request screen when the first section work area 01 is selected (refer to FIG. 8(B)) in the registration screen for the approval request target work area shown in FIG. 8(A). In FIG. 12, the left half part is an area displaying the selection screen for an approval button, and the right half part is an area displaying the display screen for a positional deviation of each steel frame (created on the basis of the positional deviation display data) which becomes a resource for decision making of approval. The area displaying this display screen for a positional deviation also displays an end button.

In the selection screen for the approval button, the number of the steel frame which belongs to the target work area (first section work area 01) is displayed in the left end portion, and the approval button (button indicating the date 2021 Sep. 1) is displayed in the right end portion. The display screen for a positional deviation shows a schematic disposition of the steel frames which belong to the target work area and the amount of positional deviation of each steel frame (the amount of positional deviation of the pillar head). As an example, regarding the steel frame 01, both the amounts of positional deviation in the X axis direction and the Y axis direction are zero.

In the following Step S204 (FIG. 11), the processing waits for selection of any button. If any button is selected (for example, clicked using a mouse) by an approver having approval authority (for example, a work site manager or the like), the processing proceeds to Step S206, and it is judged whether or not the selected button is the end button. Further, when the judgment in Step S206 is negative, the processing shifts to Step S208, and when it is positive, the processing proceeds to Step S210. Here, when the work site side computer (manager side terminal) 14 includes a display constituted of a touch panel, for example, the button displayed on the display screen may be selected by operating a mouse or may be selected by a touch operation (for example, tapping with a fingertip) similar to a smartphone or the like. In brief, a selection operation suited for the constitution of the manager side terminal operated by the approver need only be performed.

Here, the judgment in Step S206 is negative when any approval button is selected. Therefore, in Step S208, the selected button is changed to the approved state, and the date and time of approval of the steel frame corresponding to the button are stored.

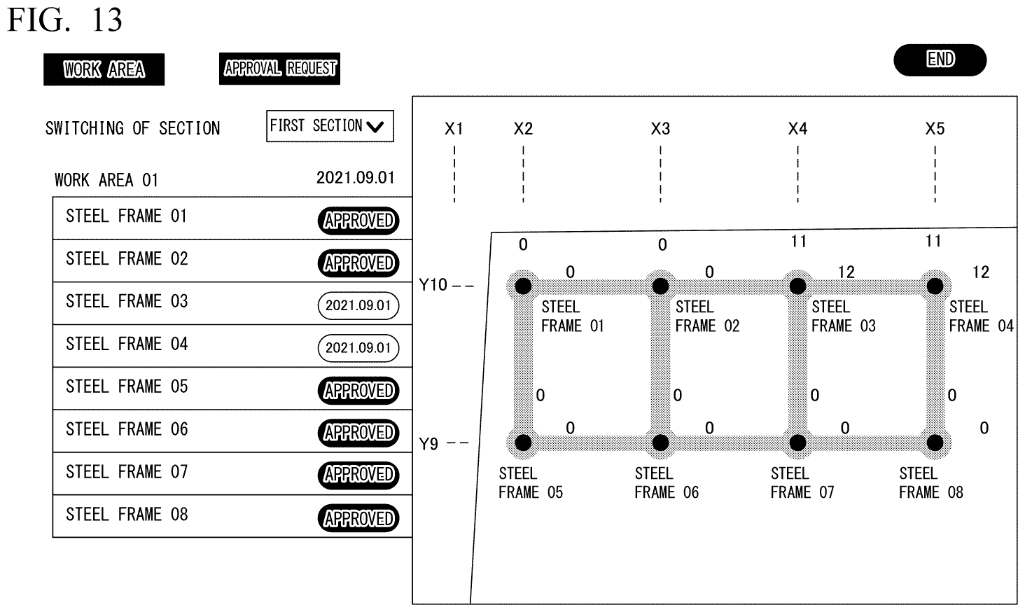

Here, a case in which the approval request screen is displayed in the foregoing Step S202 as shown in FIG. 12 will be considered. In this case, the approver looks at the display screen for a positional deviation of each steel frame in the right half part. Regarding steel frames of which the amount of positional deviation falls within an allowable value (for example, 10 mm) set in advance in both the X axis direction and the Y axis direction, it is judged that erection thereof can be approved, and it is judged that steel frames of which the amount of positional deviation has exceeded the allowable value in at least one direction cannot be approved. Further, the approver sequentially selects the approval button (for example, by clicking using a mouse) in accordance with the judgment results and then selects the end button. Accordingly, for example, the approval request screen changes as shown in FIG. 13.

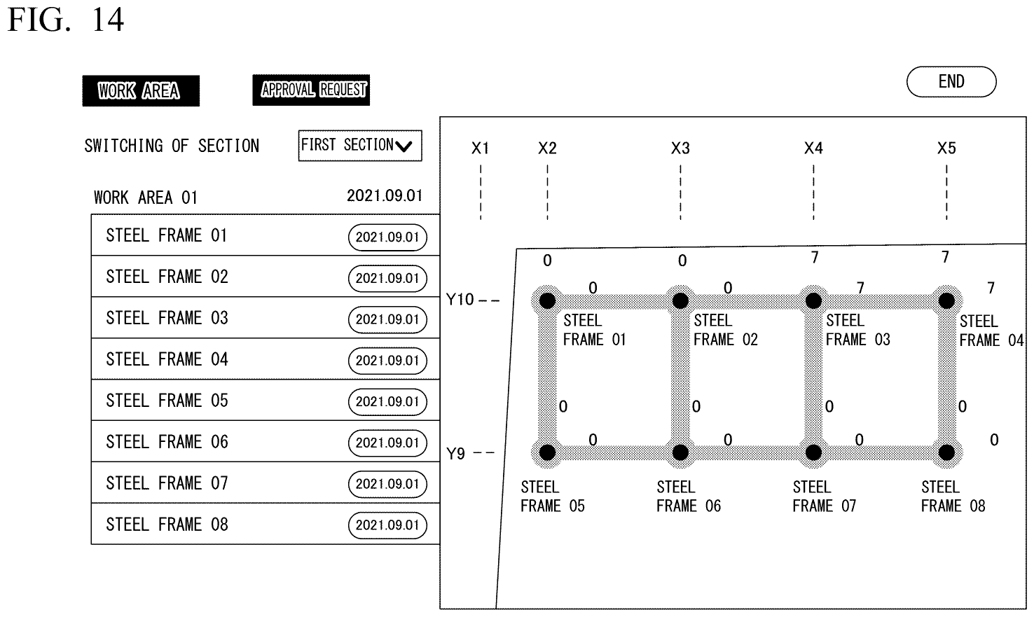

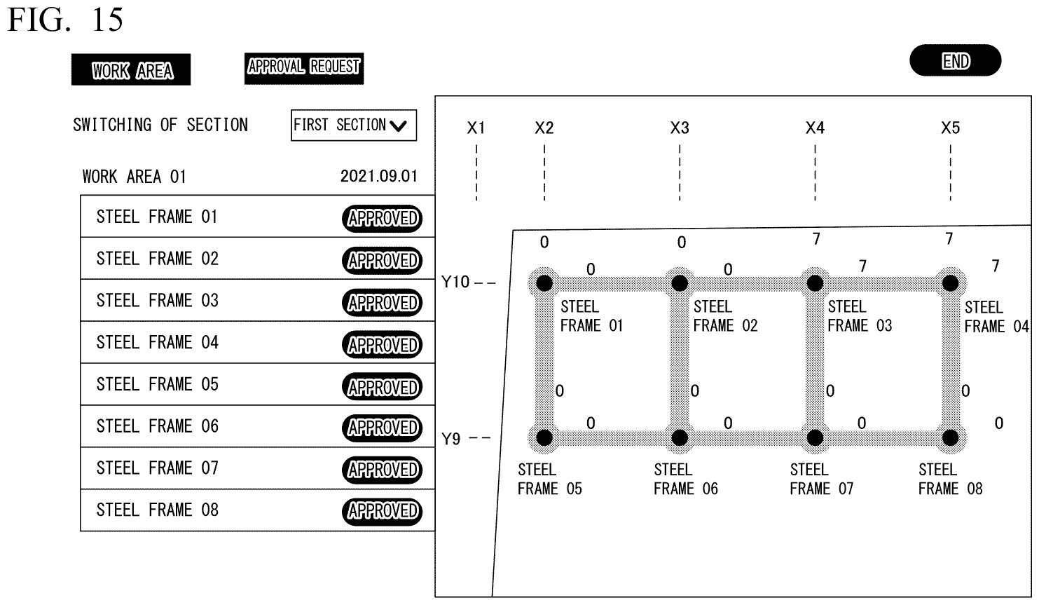

On the other hand, in the foregoing Step S202, when the approval request screen is displayed on the display screen as shown in FIG. 14, the approver looks at the display screen for a positional deviation in the right half part and judges that erection of all the steel frames can be approved. After the approval button is sequentially selected for all the steel frames in accordance with judgment results, the end button is selected. Accordingly, for example, the approval request screen changes as shown in FIG. 15.

In Step S210, after the displaying data of the approval request screen of which approval has ended, that is, the displaying data of the approval result screen is transmitted to the server 12 together with a notification command to end approval work, a series of processing of this routine ends.

In Step S114 (FIG. 9), the server 12 side is in a waiting state waiting for the approval work to end. However, the judgment in Step S114 becomes positive upon reception of the notification command and the displaying data of the approval result screen transmitted from the work site side computer 14 in the foregoing Step S210, and the processing proceeds to Step S116.

In Step S116, after the received displaying data of the approval result screen is stored in the memory and is transferred to the mobile terminal 16 with a display instruction command, the processing shifts to Step S118 (FIG. 10). Here, transfer to the mobile terminal 16 is performed after communication with the mobile terminal 16 has been established. Steps after Step S118 will be described below.

If communication between the server 12 and the mobile terminal is established during the transfer in the foregoing Step S116, an application corresponding to the flowchart in FIG. 7(B) is activated, and the flowchart in FIG. 7(B) starts.

First, in Step S60, the displaying data of the approval result screen is received together with a display instruction command.

Next, due to the loop of Steps S62 and S64, until a confirmation end button is tapped, the approval result screen is displayed on the display screen together with the confirmation end button (a button for “CONFIRMATION END”) in compliance with a display instruction command. In this case, on the display screen of the mobile terminal 16, for example, in an image of the screen shown in FIG. 13 or 15 (approval end screen), a screen in which the end button is replaced by the confirmation end button is displayed. Hence, an on-site workman who has issued a creation instruction for an approval request screen looks at the display contents on the display screen and confirms that erection of all the steel frames (when the screen of approval results corresponding to the screen in FIG. 15 is displayed) or some steel frames (when the screen of approval results corresponding to the screen in FIG. 13 is displayed) which belong to the first section work area 01 has been approved.

As a result of confirmation, when erection has not been approved for all the steel frames, rebuilding (readjustment of erection) of the steel frames which have not been approved is performed on the basis of the amounts of positional deviation of the steel frames displayed in the approval result screen.

If the confirmation end button is tapped by a workman, a series of processing ends in the mobile terminal 16.

When approval for erection is received again with respect to the same work area after readjustment has ended, the workman reactivates an application corresponding to the flowchart in FIG. 7(A).

Next, on the basis of the flowchart in FIG. 10, processing which is executed by the CPU of the server 12 concomitantly with approval work for erection of a steel frame will be described.

In Step S118 in FIG. 10, it is judged whether or not the displaying data of the approval result screen which has been transferred to the mobile terminal 16 in Step 116 described above is approved data for all the steel frames. Here, when the judgment is negative, a series of processing ends, and when it is positive, the processing proceeds to Step S120.

Here, the judgment in this Step S118 becomes positive when positional adjustment of all the steel frames which belong to the work area designated by a creation instruction for an approval request screen has been completed, that is, when the amounts of positional deviation of the pillar heads of all the pillars fall within the allowable value, and the judgment in Step S118 becomes negative in other cases.

In Step S120, the date and time of approval stored in the memory are confirmed for all the steel frames which belong to a designated work area, and it is judged whether or not the date and time of approval of the steel frame which has been approved last are the date and time after welding of the steel frame. Further, here, when the judgment is negative, a series of processing ends, and when it is positive, the processing proceeds to Step S122. The judgment in Step S120 becomes negative when approval is performed before welding of the steel frame starts, and it becomes positive when approval is performed after welding.

In Step S122, the database server 20 is accessed, and data of the pillar head positions of the target steel frames which has been calculated in Step S104 and has been stored in the memory is linked to the corresponding design data of the steel frame and is added in the database. Thereafter, a series of processing ends.

Incidentally, in the system 10 according to the present first embodiment, the server 12 can also create 3D image data visually showing a tilt state of the steel frame. Hereinafter, this will be described. As a prerequisite, as described above, after welding of each steel frame, in the database of the database server 20, it is assumed that the latest data of the pillar head position of each steel frame is linked to initial design data and is stored.

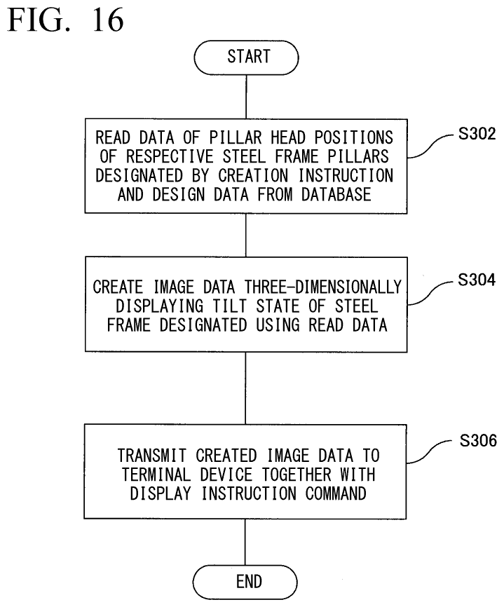

FIG. 16 shows a flowchart corresponding to a control algorithm which is executed in accordance with a program by the CPU of the server 12 in regard to creation of 3D image data visually showing a tilt state of a steel frame.

The flowchart in FIG. 16 starts when an image data creation instruction is issued from a predetermined terminal device (the work site side computer 14 as an example) connected to the network 13. An image data creation instruction includes a designation of a creation target steel frame.

In Step S302, the database server 20 is accessed, and the latest data of the pillar head position of each steel frame designated by a creation instruction and initial design data are read from the database. In the following Step S304, image data three-dimensionally displaying the tilt state of the steel frame designated by a creation instruction is created using the data read in Step S302. Specifically, the amount of positional deviation and the direction of positional deviation of the pillar head are obtained from the read latest data and initial design data of the pillar head position of each steel frame, and image data three-dimensionally showing a tilt state is created for each steel frame on the basis of the obtained results.

Further, in Step S306, after the created image data is transmitted to the terminal device, which has issued the image data creation instruction, here, the work site side computer 14 together with a display instruction command, the processing ends.

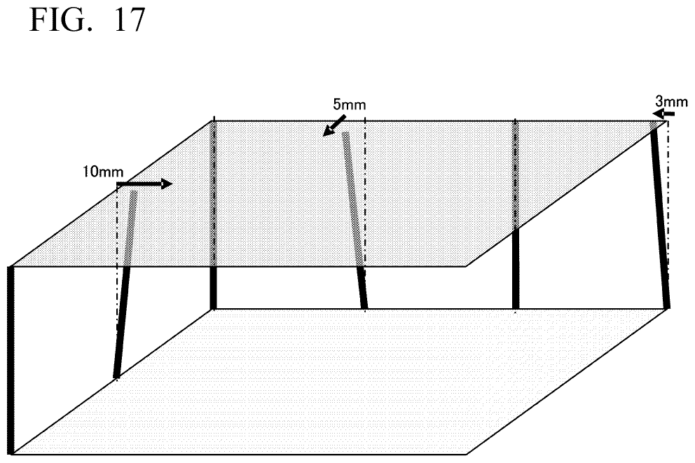

Meanwhile, the terminal device which has received the image data, here, the work site side computer 14 displays an image on the display screen in compliance with a display instruction command. Accordingly, as an example, an image shown in FIG. 17 is displayed on the display screen of the terminal device (here, the work site side computer 14). A designer (an interior designer or an exterior designer) or the like who has looked at this image can easily confirm limitation on the exterior or the interior from the tilt of the steel frame (pillar) and can determine the dimensions and the like of members to be used in interior construction and/or exterior construction in consideration of the confirmed limitation.

The image shown in FIG. 17 is an image three-dimensionally displaying the tilt state of the steel frame designated by a creation instruction. However, in another viewpoint, it is possible to understand that it is an image concurrently displaying the shapes of the steel frame designated by a creation instruction in the current and design stages. The numerical value parts in the image of FIG. 17 may be displayed together with the number of each steel frame by separately providing a table. In the description above, an image data creation instruction is issued from the predetermined terminal device to the server 12, the server 12 creates image data three-dimensionally showing a tilt state for each steel frame, and the created image data is transmitted to the terminal device which has issued the image data creation instruction together with a display instruction command. However, a predetermined terminal device may issue a creation instruction for display data of the angle of the steel frame (the amount of positional deviation and the direction of positional deviation of the pillar head) instead of an image data creation instruction. In this case, display data of the amount of positional deviation and the direction of positional deviation of the pillar head of the steel frame can be created by the server 12, and the angle of the steel frame (the amount of positional deviation and the direction of positional deviation of the pillar head) can be displayed on the display screen of the terminal device.

As described above, according to the system 10 of the present first embodiment, if an approval target work area (target work area) is designated via the mobile terminal 16 carried by a workman at a construction site and a creation instruction for an erection approval request screen is issued to the server 12, the sensor data output from the sensor devices 18ᵢ having the steel frame pillars (steel frames) which belong to a target work area, that is, the target steel frames 100ⱼ as measurement targets is acquired by the server 12, and the shapes of the target steel frames 100 are obtained and the pillar head positions are obtained from the shapes (Steps S102 and S104). At the same time, the design data of the target steel frames 100ⱼ is acquired by the server 12 from the database provided in the database server 20 (Step S106). Further, positional deviations of the pillar head positions of the target steel frames 100ⱼ are calculated by the server 12 (Step S108), the displaying data of the approval request screen of the target work area including the positional deviation display data of the target steel frames is created, and the displaying data is transmitted to the work site side computer 14 together with a display instruction command (Steps S110 and S112).

The work site side computer 14 which has received the foregoing displaying data of the approval request screen together with a display instruction command displays the approval request screen on the display screen in compliance with a display instruction command (S202). A manager who manages the work site side computer 14 looks at the approval request screen displayed on this display screen and performs approval work for erection of the steel frame.

In this way, according to the system 10 of the present first embodiment, it performs a steel frame pillar erection approval method including causing the mobile terminal 16 to issue a creation instruction for an approval request screen including a designation of a target work area to the server 12; causing the server 12 to acquire sensor data from the sensor devices 18; measuring positional information of respective steel frame pillars (target steel frames) which belong to the target work area in response to the creation instruction for an approval request screen including a designation of the target work area issued from the mobile terminal 16, obtain shapes of respective target steel frames using the sensor data, obtain pillar head positions of the respective target steel frames from the obtained shapes, create displaying data of the approval request screen including positional deviation display data of the respective target steel frames and approval request data linked to the positional deviation display data on the basis of the pillar head position and design data of the respective target steel frames, and transmit the created data to the work site side computer 14; and causing the work site side computer 14 to receive displaying data of the approval request screen, and display an approval request screen on a display screen.

Therefore, according to the present embodiment, when a workman at a construction site simply designates an approval target work area (target work area) via the mobile terminal 16 and issues a creation instruction for an erection approval request screen to the server 12, the approval request screen is displayed on the display screen of the work site side computer 14, and a manager who has looked at this approval request screen can perform approval work. Therefore, as in the related art, at construction sites of steel frame erection or the like, there is no need to perform approval work for erection of each steel frame through exchange of written documents between a workman and a manager.

In addition, since an approval selection button for each of the steel frame pillars which belong to the target work area based on the approval request data is displayed in the approval request screen (refer to FIG. 12), the manager who is in charge of approval can perform approval work by simply selecting the button using a mouse or the like.

In addition, the mobile terminal 16 displays an approved work area registration screen on the display screen (Step S52), the approved work area registration screen is configured to have a pull-down menu for each of the plurality of items and is constituted to be able to select input data of each of the items (refer to the (A) part and the (B) part of FIG. 8), and selection of input data of each of the plurality of items is automatically reflected in designation of the target work area included in a creation instruction for an approval request screen (Step S58). Therefore, creation of the approval request screen is extremely simple.

Moreover, when the displaying data of the approval result screen is received from the work site side computer 14 after the displaying data of the approval request screen is transmitted, the server 12 transfers the received displaying data of the approval result screen to the mobile terminal 16 (Step S116), and the mobile terminal 16 receives the transferred displaying data of the approval result screen and displays the approval result screen on the display screen (Steps S60 and S62). An on-site workman who has looked at this approval result screen can immediately know whether or not erection of each steel frame which belongs to the target work area has been approved.

In this way, according to the system 10 of the present first embodiment, approval work for erection of a steel frame can be made efficient.

In addition, according to the system 10 of the present first embodiment, when it is confirmed that transferred displaying data is approved data which has been approved after welding of all the steel frame pillars (steel frames) included in the displaying data after the received displaying data of the approval result screen is transferred to the mobile terminal 16 (when both the judgment results of Steps S118 and S120 described above are Yes), the server 12 accesses the database server 20, links the calculation results of the pillar head positions of the respective steel frame pillars which belong to the target work area stored in the memory to design data of the respective steel frame pillars which belong to the target work area, and stores the linked data in the database (Step S122).

In this way, in a stage in which erection of the steel frames which belong to the target work area (the final process is erection measurement of the steel frames after welding) has ended, the data of the pillar head positions of each steel frames is linked to the design data and is stored in the database. Therefore, during erection of the steel frame in the upper section of the steel frames (target steel frames) which belong to the target work area (which will be performed below), for example, even after the sensor devices installed in the target steel frames are detached, an erection target position can be determined in consideration of data of the pillar head positions of the target steel frames stored in the database.

In addition, according to the system 10 of the present first embodiment, in response to an image data creation instruction issued from any terminal device, for example, the work site side computer 14 (or the mobile terminal 16) or the like connected via the network 13, the server 12 reads design data of the respective steel frame pillars designated by an image data creation instruction and data of the calculation results of the pillar head positions of the respective steel frame pillars linked to this from the database (S302), creates image data three-dimensionally displaying the tilt state of the steel frame designated using the read data (Step S304), and transmits the created image data together with a display instruction command to the terminal device which has issued an image data creation instruction (Step S306). Accordingly, an image three-dimensionally displaying the tilt state of the designated steel frame is displayed on the display screen of the terminal device. A designer (an interior designer or an exterior designer) or the like who has looked at this image can easily confirm limitation on the exterior or the interior from the tilt of the steel frame (pillar) and can determine the dimensions and the like of members to be used in interior construction and/or exterior construction in consideration of the confirmed limitation.

According to the system 10 of the present first embodiment, since the shape information of the steel frame pillar can be acquired before exterior construction starts, adjustment of an exterior panel using a jig can also be performed in a factory.

According to the system 10 of the present first embodiment, it is sufficient for the database provided in the database server 20 to store the design data of each steel frame. Therefore, for example, the database may be a database for building information modeling (BIM) (which will hereinafter be referred to as a BIM database), which has been recently introduced by general construction companies known as general contractors. BIM is a solution for utilizing information of a building in the database to which attribute data, such as costs, finishing, and management information, is added in every process from design and construction to maintenance management in a digital model of a three-dimensional building created on a computer, and is a new workflow for construction which changes due to this.

In the present embodiment, when the database server 20 (may be a cloud) includes the BIM database as its database, after welding of the steel frame which belongs to one work area of one section has ended as an example, every time the approval work described above is performed, in Step S122 described above, data of the pillar head positions of all the steel frames which belong to the work area is linked to the design data of the steel frames and is added to the database. Further, construction drawings for the next process are inevitably created based on the information of the BIM database after this addition. For example, in consideration of the position of the pillar head after updating of the steel frames which belong to a certain work area of a certain section, the erection target position of a steel frame in the upper section of the steel frame is determined. That is, it is possible to partially realize reflection of the construction status in upstream drawings and handover to the next construction process. In this way, according to the present embodiment, BIM can be utilized not only in design before construction but also in the stage after construction. The database server 20 may be a BIM cloud.

In the foregoing first embodiment, as an example, a case in which the system 10 includes the database server 20 separately from the server 12 has been described. However, it is not limited to this, and the server 12 or other terminal devices which can be accessed by the server 12 may have the function of a database server. That is, a database (it may be or may not be a BIM database, but it stores at least design data of each steel frame) may be saved (stored) in the storage included in the server 12 or other terminal devices. In this case, access to the storage storing the database is performed instead of access to the database server. The same also applies to second and third embodiments which will be described below.

In the foregoing first embodiment, a case in which six sensor devices are attached to the respective steel frame pillars has been described. However, it is not limited to this. The number of sensor devices does not particularly matter as long as the shapes of the first surface and the second surface of the steel frame pillar can be obtained. In addition, for example, when simply obtaining the XY position of the pillar head of the steel frame or a positional deviation from a reference position thereof, for example, it is sufficient to simply attach two sensor devices to the pillar head portion.

In the description so far, an on-site workman issues an instruction to start approval processing to the server 12 via the mobile terminal 16, and the mobile terminal 16 receives the displaying data of the approval result screen in which approval of the approver has ended from the server 12 as a response. Further, a case in which an on-site workman acquires positional deviation information of each steel frame together with approval results when the approval result screen is displayed on the display screen of the mobile terminal 16 has been described. However, as in the second embodiment which will be described below, regardless of approval, an on-site workman may acquire positional deviation information of each steel frame using the mobile terminal 16 and the server 12.

As described above, when rebuilding of a steel frame has ended, when bolt tightening of the pillar couplers has ended, when welding of a steel frame has ended, or the like, in the case in which an on-site workman desires to receive approval for erection accuracy of a steel frame from an approver (a manager or the like), a creation instruction for an approval request screen is performed with respect to the server 12 via the mobile terminal 16. However, erection measurement is performed as a prerequisite for this, and from the results of the erection measurement, a creation instruction for an approval request screen is performed at the point of time when an on-site workman judges that the tilt amount of the target steel frame has fallen within an allowable range. When the tilt amount of the target steel frame has fallen within the allowable range, all the tilt angles measured by the respective sensor devices 18ᵢ attached to the target steel frame fall within the allowable range, and the workman confirms this at the point of time when a creation instruction for an approval request screen is performed. However, due to a human error such as misunderstanding, there is a probability that a creation instruction for an approval request screen will be performed even if the tilt amount of the target steel frame does not fall within the allowable range (at least one of the tilt angles measured by the respective sensor devices 18ᵢ described above exceeds the allowable range). In this case, it is preferable to perform error-displaying (change the display color and the like) indicating that the steel frame exceeding the allowable range is out of the allowable range in the approval request screen (for example, refer to FIG. 12) which is created on the basis of a creation instruction for an approval request screen and is displayed on the display screen of the manager side terminal (work site side computer 14). Moreover, the approver is not allowed to approve the steel frame which is out of the allowable range. For example, the approval button shown in FIG. 12 is made not selectable. Alternatively, the server 12 may instruct an on-site workman to perform readjustment before approval of the approver. For example, if it is confirmed that the tilt amount of the target steel frame has exceeded the allowable range at the point of time when the server 12 has acquired the sensor data from the sensor devices 18ᵢ (at the point of time before the shape is obtained), information instructing readjustment is displayed on the display screen of the mobile terminal 16.

Furthermore, regarding the steel frame of which the tilt amount is out of the allowable range, an on-site workman may be prevented from being able to apply approval and may immediately instruct readjustment. If the tilt angles of all the steel frames do not fall within the allowable range, the computer may prevent a workman from requesting approval for all the steel frames.

### Second Embodiment

Next, the second embodiment will be described.

In the present second embodiment, it is assumed that a system having the same constitution as that of the system 10 according to the first embodiment described above is used. However, since the present second embodiment does not require approval of a work site manager as a prerequisite, the system according to the present second embodiment may not include the work site side computer 14.

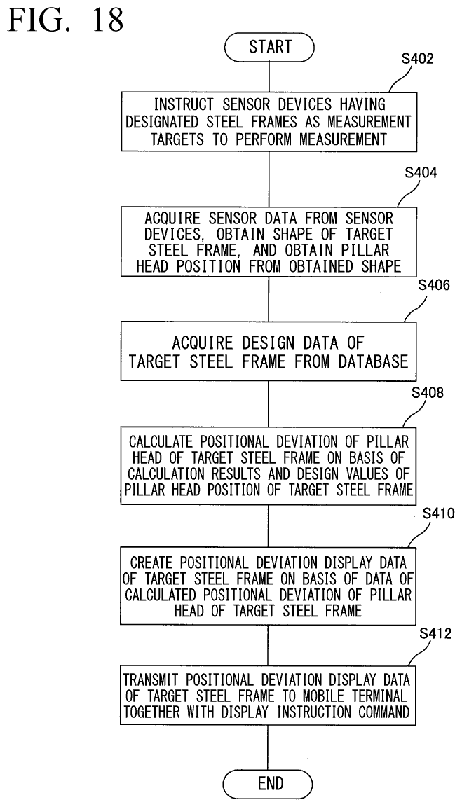

FIG. 18 shows a flowchart corresponding to a processing algorithm which is executed in accordance with a program by the CPU of the server 12 in the system according to the present second embodiment. A program corresponding to this processing algorithm is installed in advance in the server 12.

The flowchart in FIG. 18 starts when a command of an inquiry for a positional deviation of the pillar head of the steel frame is issued from the mobile terminal 16 to the server 12 via the network 13 in response to an input operation of an on-site workman. Here, it is conceivable that a command of an inquiry for a positional deviation of the pillar head of the steel frame is issued from an on-site workman to the server 12 via the mobile terminal 16, for example, before erection adjustment or rebuilding starts. It is assumed that a command of an inquiry for a positional deviation of the pillar head of the steel frame includes a designation of a target steel frame. Here, a designation of the steel frame may be performed in units of a steel frame or may be performed in units of a plurality of steel frames. However, here, as an example, it is performed in units of one work area of one section (which will hereinafter be referred to as a designated work area). If the shape of a steel frame changes, a positional deviation of the pillar head of the steel frame occurs. Therefore, obtaining a change in shape of the steel frame becomes one means for obtaining a positional deviation of the pillar head of the steel frame. Therefore, it can be said that an inquiry for a positional deviation of the pillar head of the steel frame is a form of an inquiry for change in shape of the steel frame.

First, in Step S402, the plurality of sensor devices 18ᵢ having the designated steel frames, here, all the steel frames which belong to the designated work area as the measurement targets are instructed to perform measurement.

In the following Step S404, the sensor data is acquired from the plurality of sensor devices 18ᵢ instructed to perform measurement. The shape of the target steel frame (a function indicating a shape) is obtained by the method described above using the measurement results at the measurement points in the steel frame (which will hereinafter be referred to as a target steel frame) that is the measurement target of each of the sensor devices 18ᵢ, and the pillar head position of the target steel frame is obtained from the obtained shape. Next, in Step S406, the database server 20 is accessed, and the design data of the target steel frame is acquired from the database.

In the following Step S408, the positional deviation of the pillar head of the target steel frame is calculated on the basis of the calculation results and the design values of the pillar head position of the target steel frame, and in the following Step S410, the positional deviation display data of the target steel frame is created on the basis of the data of the calculated positional deviation of the pillar head of the target steel frame.

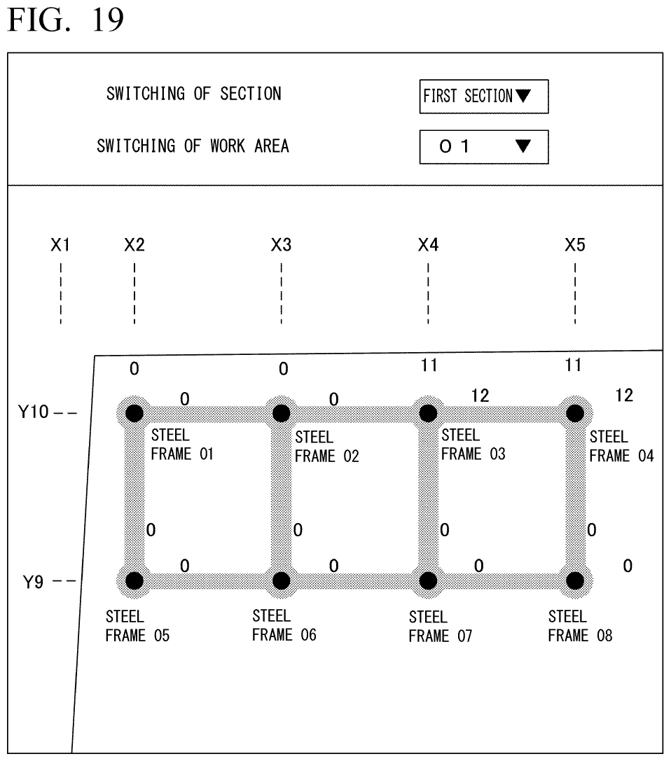

Further, in the following Step S412, the positional deviation display data of the target steel frame is transmitted to the mobile terminal 16 together with a display instruction command. Accordingly, an image corresponding to the positional deviation display data of the target steel frame (in this case, the steel frame which belongs to the designated work area) is displayed on the display screen of the mobile terminal 16. As an example, an image (display screen for a positional deviation) is displayed on the display screen of the mobile terminal 16 as shown in FIG. 19. An on-site workman who has looked at this screen and has performed an inquiry for a positional deviation can judge that no additional positional deviation adjustment is required for the steel frames other than the steel frame 03 and the steel frame 04. In addition, regarding the steel frame 03 and the steel frame 04 as well, the amount of positional deviation in each of the X axis direction and the Y axis direction can be ascertained, and therefore readjustment is facilitated.

Even in the present second embodiment, the BIM database described above may be used as a database.

In the foregoing the first and second embodiments, a case in which approval for erection of a steel frame or an inquiry for a positional deviation of a steel frame is performed in in units of one work area of one section has been described. However, it is not limited to this, and approval for erection of a steel frame or an inquiry for a positional deviation of a steel frame can also be performed in units of at least one steel frame. In such a case, there is a need for the foregoing programs (applications) executed by each of the mobile terminal 16, the server 12, and the work site side computer 14 to be rewritten in accordance with the units.

In addition, for example, in the foregoing second embodiment, in place of display of a positional deviation by the display screen as shown in FIG. 19 which two-dimensionally displays a positional deviation, data of an image concurrently displaying the shape of the steel frame in the current and design stages similar to the image as shown in FIG. 17 which three-dimensionally displays the tilt of the steel frame can also be displayed on the display screen as the positional deviation display data. Alternatively, a constitution switchable between two modes of a display method using these two methods for displaying a positional deviation may be adopted.

### Third Embodiment

Next, the third embodiment will be described.

In the present third embodiment, it is assumed that a system having the same constitution as that of the system 10 according to the first embodiment described above is used. However, similar the second embodiment described above, the system according to the present third embodiment may not include the work site side computer 14.

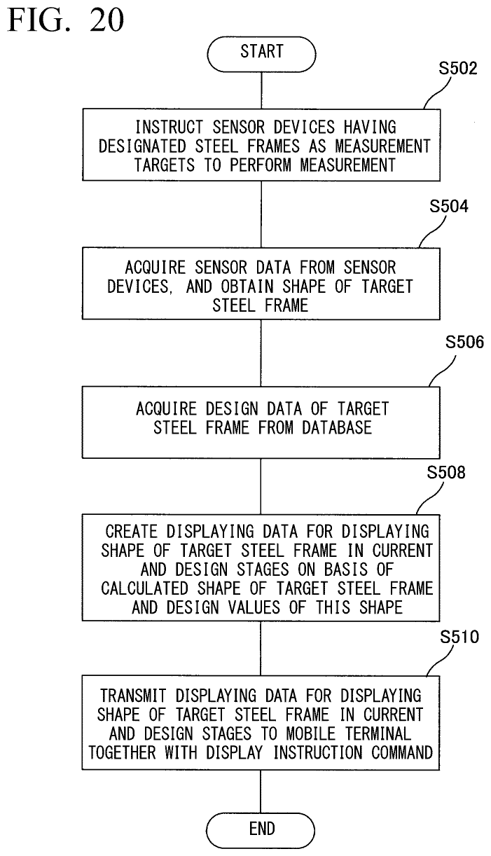

FIG. 20 shows a flowchart corresponding to a processing algorithm which is executed in accordance with a program by the CPU of the server 12 in the system according to the present third embodiment. A program corresponding to this processing algorithm is installed in advance in the server 12.

The flowchart in FIG. 20 starts when a command of an inquiry for change in shape of the steel frame is issued from the mobile terminal 16 to the server 12 via the network 13 in response to an input operation of an on-site workman. It is assumed that a command of an inquiry for change in shape of the steel frame includes a designation of a target steel frame. Here, a designation of the steel frame may be performed in units of a steel frame or may be performed in units of a plurality of steel frames. However, here, as an example, it is assumed that one selected steel frame (for example, the steel frame 100₁) is designated.

First, in Step S502, a plurality of (here, six) sensor devices 18ᵢ having the designated steel frames as the measurement targets are instructed to perform measurement.

In the following Step S504, the sensor data is acquired from the plurality of sensor devices 18ᵢ instructed to perform measurement. The shape of the target steel frame (a function indicating a shape) is obtained by the method described above using the measurement results at the measurement points in the steel frame (which will hereinafter be referred to as a target steel frame) that is the measurement target of each of the sensor devices 18ᵢ. Next, in Step 506, the database server 20 is accessed, and the design data of the target steel frame is acquired from the database.

In the following Step S508, displaying data for displaying information related to the shape (current shape) of the target steel frame obtained in Step S504 and the shape in the design stage included in design data is created.

Further, in the following Step S510, displaying data for displaying information related to shapes of the target steel frame in the current and design stages is transmitted to the mobile terminal 16 together with a display instruction command. Accordingly, the display contents corresponding to the displaying data for displaying information related to shapes of the target steel frame in the current and design stages are displayed on the display screen of the mobile terminal 16. An on-site workman who has looked at this screen and has performed an inquiry for change in shape can easily recognize a change in shape of the target steel frame.

In the foregoing third embodiment, a case in which the measurement targets of the sensor devices 18ᵢ are steel frame pillars (steel frames) has been described. However, the measurement target need only be a member to which the sensor devices 18ᵢ are attached, for example, a member constituting infrastructure, a vehicle, and other moving objects. Specifically, it may also be a member constituting at least one of a building, a bridge, a tunnel, an express way, a dam, a wind turbine, a power plant (hydroelectric, thermoelectric, natural gas, nuclear, or the like), an automobile (F1 car or the like), an aircraft and other flying objects (a rocket, a missile, a spacecraft, or the like), a high-speed train, a ship, a submarine, and a deep-sea exploration vessel.

When the measurement target is a member constituting infrastructure, a vehicle, and other moving objects, the database provided in the server 12 (or the database server 20) stores design data of the infrastructure, the vehicle, and other moving objects correspondingly to the member.

Those involved in manufacturing, maintenance, management, and the like of the foregoing infrastructure, the vehicle, and other moving objects may desire to know change in shape of the members (including a positional deviation in a predetermined part) which are the measurement targets of the sensor devices 18ᵢ. In such a case, display contents corresponding to displaying data for displaying information related to shapes of the measurement target member in the current and design stages can be displayed the display screen of the terminal device similarly to the foregoing third embodiment by inquiring of the server regarding change in shape of the measurement target member via the sensor devices 18ᵢ, the server (management device), and the terminal device connected to the network.

The terminal device for making an inquiry for change in shape is not limited to a mobile terminal. It need only be a terminal device connected to the foregoing network.

In the foregoing third embodiment, the server 12 may create displaying data for displaying information for correcting at least one of the interior and the exterior on the basis of the data of the shapes of the steel frame pillars obtained in Step S504 described above, and may transmit the displaying data to the mobile terminal 16 together with a display instruction command. The information for correcting at least one of the interior and the exterior can include information with which limitation on the interior and the exterior can be easily confirmed. This information is displayed on the display screen of the mobile terminal 16. A workman who has looked at this screen and has performed an inquiry for change in shape can determine the dimensions of the members used in interior construction and/or exterior construction in consideration of the limitation. In addition, in the foregoing third embodiment, the server 12 may store the data of the shapes of the steel frame pillars obtained in Step S504 described above in the database as CAD data. The creation of displaying data for displaying the information for correcting at least one of the interior and the exterior which has been described here and storage of the shapes of the steel frames obtained from the sensor data in the database of CAD data can also be applied to the first and second embodiments described above.

In the foregoing embodiments, a case in which IDs of the sensor devices 18ᵢ (including information indicating the sensor numbers and the attachment positions of the sensor devices) are input by a worker during initial setting performed by the worker when the sensor devices 18ᵢ are attached to the object and the server 12 manages the attachment position of each of the sensor devices by including the IDs in the sensor data has been described. However, by changing a part of the constitution of the system 10, the workman will not necessarily have to perform manual work such as an input of identification information (ID) which is troublesome and is likely to cause a human error when the sensor device are attached to the object.

Hereinafter, a method and a device for acquiring information related to a correspondence between each of a plurality of sensor devices and a measurement target (an object and measurement points thereof), which can also be favorably used in each of the foregoing embodiments, will be described.

### Fourth Embodiment

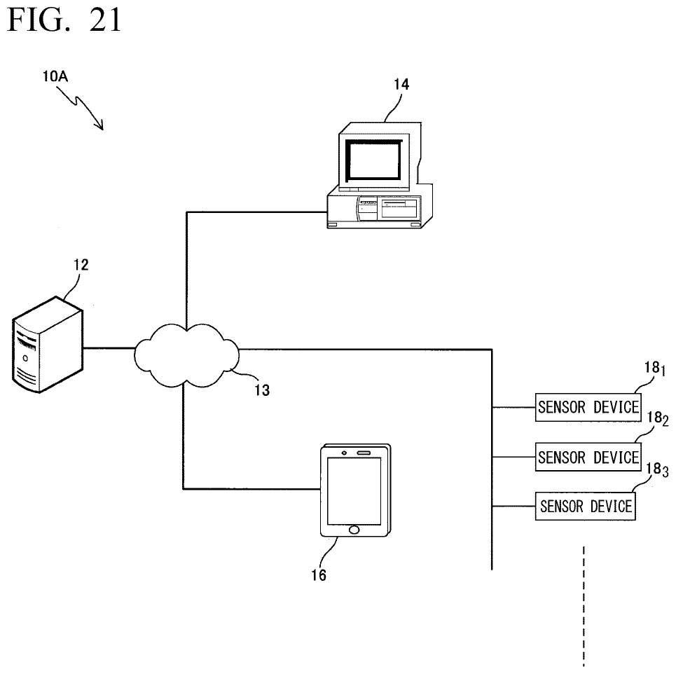

Hereinafter, a fourth embodiment will be described on the basis of FIGS. 21 to 32. Here, the same reference signs are used for the constituent parts which are the same or equivalent to those of the first embodiment described above, and description thereof will be omitted except for when it is particularly necessary. In the present embodiment as well, as an example, a case in which an object to which the sensor devices are attached, that is, an object of measurement (measurement target) by the sensor devices is a steel frame pillar 100 constituting the steel frame building 110 shown in FIG. 3 described above will be described, but the object is not limited to a steel frame pillar.

FIG. 21 schematically shows an overall constitution of a shape acquisition system 10A according to the fourth embodiment.

The shape acquisition system 10A is constituted to include the server 12, the work site side computer 14, the mobile terminal 16, and a plurality of sensor devices 18ₚ (p=1, 2, 3, and so on), which also function as management devices connected to each other via the wide area network (which will hereinafter be suitably abbreviated to a network) 13 such as the Internet. The plurality of sensor devices 18ₚ are connected to the network 13 via communication lines, for example, a wireless LAN. FIG. 21 representatively shows three sensor devices 18₁ to 18₃ of the plurality of sensor devices 18ₚ. All the communication lines may be wireless, but at least a part may be wired. Hereinafter, one network constituted to include the network 13 and all the communication lines connecting the server 12, the work site side computer 14, the mobile terminal 16, and the plurality of sensor devices 18ₚ to the network 13 will be indicated as the network 13 using the same reference sign as the wide area network 13.

As is clear from a comparison between FIGS. 21 and 1, the shape acquisition system 10A has an overall constitution realized by removing the database server 20 from the system 10 according to the first embodiment described above.

However, in the present embodiment, regarding the mobile terminal 16, as an example, a near field communication (NFC) smartphone conforming to the communication standard of NFC is used. The NFC smartphone includes a camera. The mobile terminal 16 may be a generally used portable computer, for example, a tablet PC as long as it has functions similar to those of the NFC smartphone. In the present embodiment as well, the mobile terminal 16 is carried by a workman at a construction site.

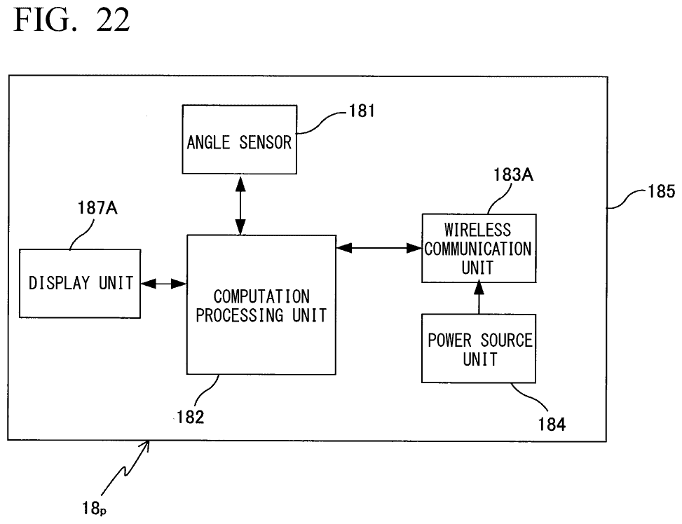

In the present embodiment, devices having the constitution shown in FIG. 22 are used as the sensor devices 18ₚ (i=1, 2, 3, and so on). The sensor devices 18ₚ have a constitution provided with a display unit 187A and a wireless communication unit 183A in place of the display operation unit 187 and the communication unit 183 included in the sensor devices 18ₚ shown in FIG. 2.

The computation processing unit 182 is constituted of a microcontroller unit (MCU), as an example. The computation processing unit (which will hereinafter be suitably referred to as a controlling microcomputer) 182 executes a processing algorithm stipulated by a program stored in the memory device. The controlling microcomputer 182 rewrites various kinds of information stored in the memory device, a memory domain in an HF band IC (which will be described below), or the like and performs control for rewriting display contents of the display unit 187A. Further, the controlling microcomputer 182 controls the sensor devices 18ₚ in their entirety. The controlling microcomputer 182 is connected to the HF band IC (which will be described below), an HF band antenna, and the like. The controlling microcomputer 182 is electrically connected to the display unit 187A and the angle sensor 181 through a wired inter-integrated circuit (I²C) interface or the like. The memory device can be constituted of an EEPROM, a FeRAM, or the like. Instead of providing the computation processing unit 182, an ASIC built into the angle sensor 181 may also have the function of the computation processing unit 182.

The wireless communication unit 183A includes the HF band IC, the HF band antenna, and the like (none is shown). Furthermore, a UHF band IC, a UHF band antenna, and the like may be included.

The HF band IC is an IC for wireless communication for performing near field communication using a HF frequency band of 13.56 MHz and performs wireless communication with an external reader/writer terminal via the HF band antenna. For example, the HF band IC is an I²C-mounted HF RFIC and is connected to the controlling microcomputer (computation processing unit) 182 via a bus such as an I²C. In consideration of the amount of data, the low-power consumption, and the optimal transfer speed, an I²C is preferably adopted as a connection bus for connecting the HF band IC and the controlling microcomputer 182, but it is not limited to this. The HF band IC stores data acquired from an external reader/writer terminal via the HF band antenna in a user memory domain of the memory device or the memory domain in the HF band IC via the CPU of the controlling microcomputer 182.

Since the wireless communication unit 183A includes the HF band IC and the HF band antenna described above, the sensor devices 18ₚ can communicate a reader/writer terminal, an NFC smartphone (for example, the mobile terminal 16), and the like conforming to the communication standards of ISO/IEC 14443, ISO/IEC 15693, ISO/IEC 18092, FeliCa (registered trademark), NFC, and the like.

In addition, the wireless communication unit 183A also functions as a Wi-Fi communication (wireless LAN communication) unit. The sensor devices 18ₚ can perform wireless LAN communication with the server 12 and other instruments connected to the network 13 via the network 13. A wired communication unit may be provided in place of a part of the wireless communication unit 183A except for the HF band IC and the HF band antenna.

For example, the display unit 187A may be constituted of an electronic paper using an electrophoresis method, a ferroelectric liquid crystal, a cholesteric liquid crystal, an electrochromic liquid crystal, or the like. In the present embodiment, as an example, a dot-matrix display-type electronic paper performing display having non-volatile memory properties is used. Therefore, hereinafter, suitably, the display unit 187A is also referred to as the electronic paper 187A, and a screen thereof will also be referred to as a display panel.

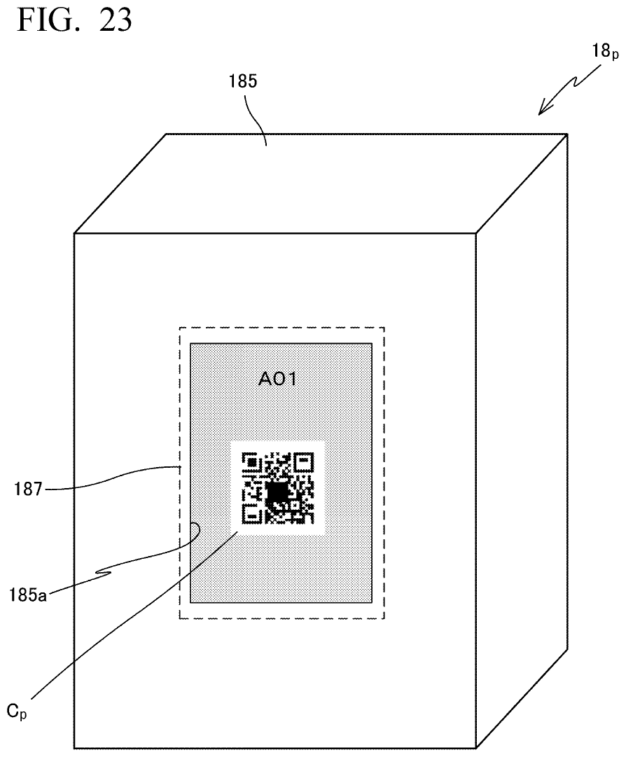

FIG. 23 schematically shows a perspective view of an appearance of the sensor device 18ₚ. As shown in this FIG. 23, a rectangular opening 185a is formed on the front surface of the casing 185 of the sensor device, the electronic paper 187A is disposed in a state in which the opening 185a is covered from the rear surface side, and the display panel is positioned inside the opening 185a. In addition, the display panel is protected by a transparent member which is fitted into the opening 185a. That is, as shown in FIG. 23, the display panel can be seen from the outside via the opening 185a. In the present embodiment, in each of the sensor devices 18ₚ, an identifier, as an example, a QR code (registered trademark) Cₚ that is a kind of a two-dimensional code storing a sensor number unique to the sensor device is written in the memory domain of the HF band IC (or the user memory domain of the memory device of the computation processing unit 182) using a reader/writer terminal conforming to the communication standard such as NFC in a manufacturing factory, and the written QR code Cₚ is displayed in the display panel. Here, the QR code is used because the presence of cutout symbols at three locations allows stable and fast reading in any direction around 360° and this is suitable for reading using a camera. As a matter of course, a two-dimensional code or a barcode other than a QR code may be used as an identifier. Without being limited to this, other codes, a symbol, a sign, or the like may be used as an identifier. For example, a combination of numerals and alphabets, or the like may be used as an identifier.

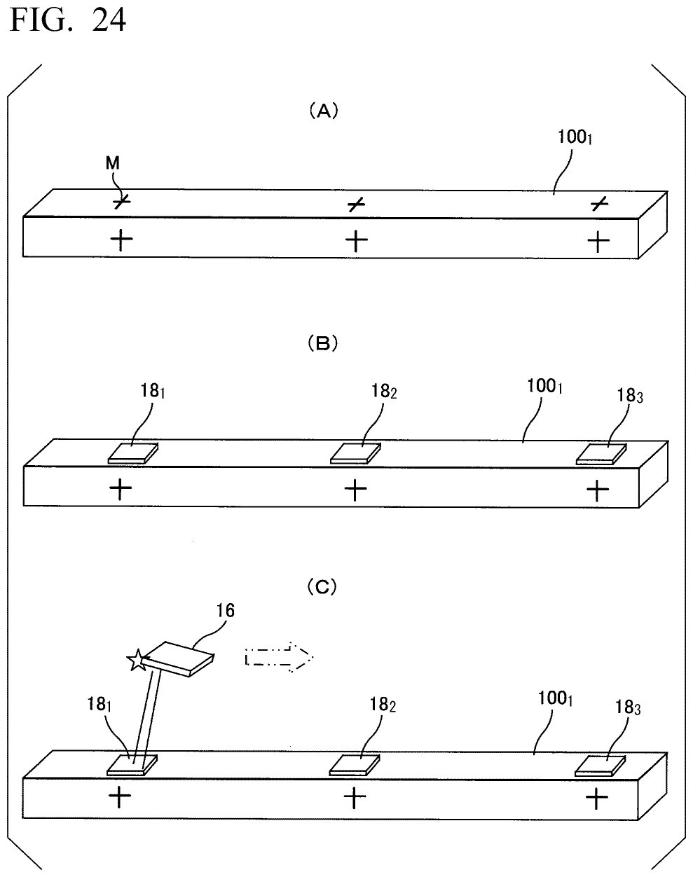

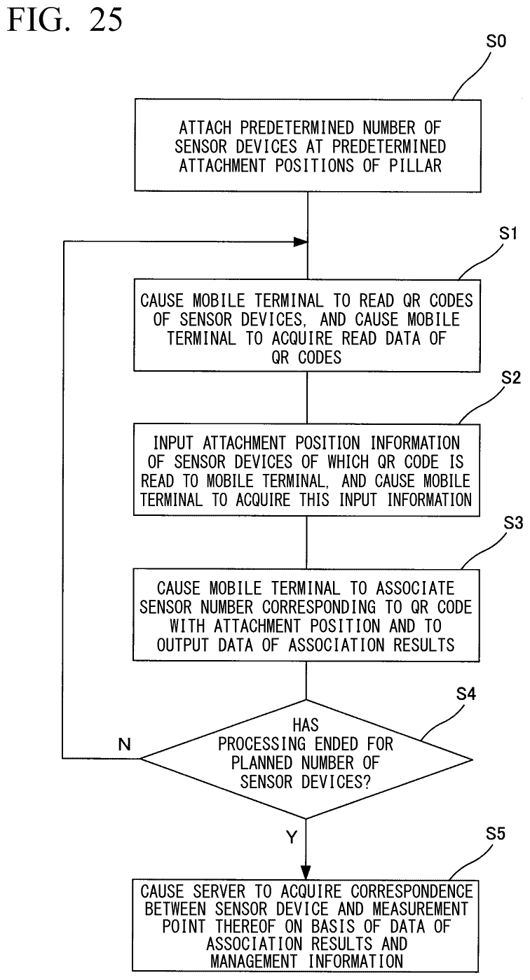

Next, an information acquisition method according to the present embodiment will be described on the basis of the (A) part of FIG. 24, the (B) part of FIG. 24, the (C) part of FIG. 24, and FIG. 25 by taking a steel frame pillar (which will hereinafter be suitably abbreviated to a pillar) as an object to which a plurality of sensor devices 18ₚ are attached. Here, in order to simply the description, as an example, a case in which the three sensor devices 18₁ to 18₃ are attached to the first surface of the pillar 100₁ shown in FIG. 4 will be described.

Before being erected, the pillar 100₁ is delivered to a place in the vicinity of a predetermined erection position set in advance within a construction site with the first surface facing upward. FIG. 24(A) shows the delivered pillar 100₁.

FIG. 25 shows a flowchart of a flow of processing of the information acquisition method. First, as shown in FIG. 24(B), a predetermined number of (here, three) sensor devices 18ₚ are attached to the first surface of the pillar 100ⱼ (here, the pillar 100₁) (Step S0 in FIG. 25). In the pillar 100ⱼ, a predetermined number of (here, three) marks M are provided in advance on the first surface (the upper surface in FIG. 24(A)), and the sensor devices 18₁ to 18₃ are attached in a manner of being centered around the positions of the marks M. The sensor devices 18₁ to 18₃ are attached to the pillar 100₁ utilizing magnetic forces of permanent magnets (not shown), as an example, by a workman before erection of the pillar 100₁. The sensor devices do not necessarily need to be attached utilizing a magnetic force, and bolt fastening or other fixing methods may be used. Here, magnetic forces of permanent magnets are used in consideration of relatively easy attachment and detachment.

Next, as shown in FIG. 24(C), the QR codes Cₚ (refer to FIG. 23) displayed in the display panels of the sensor devices 18ₚ are read (image-captured) using the mobile terminal 16, and the CPU of the mobile terminal 16 stores the read (image-captured) data of the QR codes Cₚ in the memory (Step S1 in FIG. 25). Here, the QR codes are read by a worker at a work site using the camera of the mobile terminal 16.

Next, attachment position information of the sensor devices 18ₚ, of which the QR code is read, are input to the mobile terminal 16, and the CPU of the mobile terminal 16 stores the input information in the memory (Step S2 in FIG. 25). Here, the attachment positions correspond to the measurement points (measurement points where information of the tilt angle (tilt information) in at least one direction of the θy direction and the θx direction is measured) in the pillar 100₁ by the sensor devices after erection. Here, the attachment position information is input by a worker at a work site. Before pillars are delivered to a construction site, the server 12 has acquired data of design drawings of the steel frame building 110 and the like through exchange with the work site side computer 14 via the network 13, and the server 12 sets the attachment positions such that the measurement points by the sensor devices 18ₚ match the attachment positions on the basis of the data of this design drawings.

Next, the CPU of the mobile terminal 16 associates the sensor numbers (the numbers unique to the sensor devices) obtained by character-converting dots included in the acquired (read) QR codes with the acquired data of the attachment position and outputs data of the association results (Step S3 in FIG. 25).

Next, it is judged whether or not processing has ended for the planned number of (here, three) sensor devices (Step S4 in FIG. 25). When the judgment thereof is negative, the processing returns to Step S1, and processing of the foregoing Steps S1 to S3 is performed for the next sensor device. Meanwhile, if the processing for the planned number of sensor devices ends, the judgment in Step S4 becomes positive, and the processing shifts to Step S5.

In Step S5, the server 12 acquires a correspondence between the sensor devices and the measurement points (measuring points) thereof on the basis of the data of the foregoing association results and the predetermined management information. Here, management information includes design information of the attachment positions.

Through a flow of the processing of the foregoing Steps S1 to S5, the correspondence information between the sensor number and the measurement point thereof is acquired for each of the plurality of (here, three) sensor devices.

Similarly, for other pillars 100ⱼ (=2, 3, and so on) as well, the correspondence information between the plurality of sensor devices 18ₚ (sensor numbers) attached to the first surface and the measurement points thereof is acquired.

The correspondence information between the plurality of sensor devices 18ₚ attached to the second surface of each of the pillars 100ⱼ (j=1, 2, 3, and so on) and the measurement points thereof is obtained in a similar procedure, for example, around the time of acquiring the foregoing correspondence information for the plurality of sensor devices attached to the first surface described above.

Here, the processing of the mobile terminal 16 in the foregoing Steps S1 to S4 and the processing of the server 12 in Step S5 will be described in more detail.

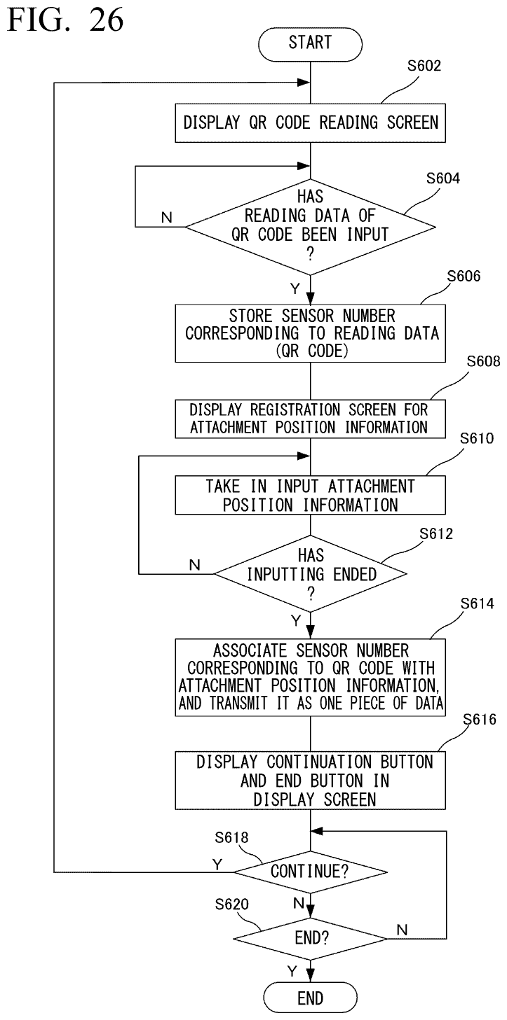

FIG. 26 shows a flowchart corresponding to a processing algorithm of the CPU of the mobile terminal 16 corresponding to the foregoing Steps S1 to S4. An application (program) corresponding to this processing algorithm is installed in advance in the mobile terminal 16.

The flowchart in FIG. 26 starts with activation of the foregoing application.

First, in Step S602, the QR code reading screen is displayed in the display screen. For example, this reading screen displays “Please read the QR code displayed in the sensor device” or the like together with a reading frame (mark).

In the following Step S604, the processing waits for reading data of the QR code to be input. Further, if a worker reads the QR code Cₚ (here, C₁) displayed on the display panel of the sensor device 18ₚ (here, the first sensor device 18₁) using the camera of the mobile terminal 16 and the reading data thereof is input, the processing proceeds to Step S606, and the sensor number corresponding to the QR code Cₚ included in the reading data (the sensor number obtained by character-converting dots included in the QR code) is stored in the memory (RAM).

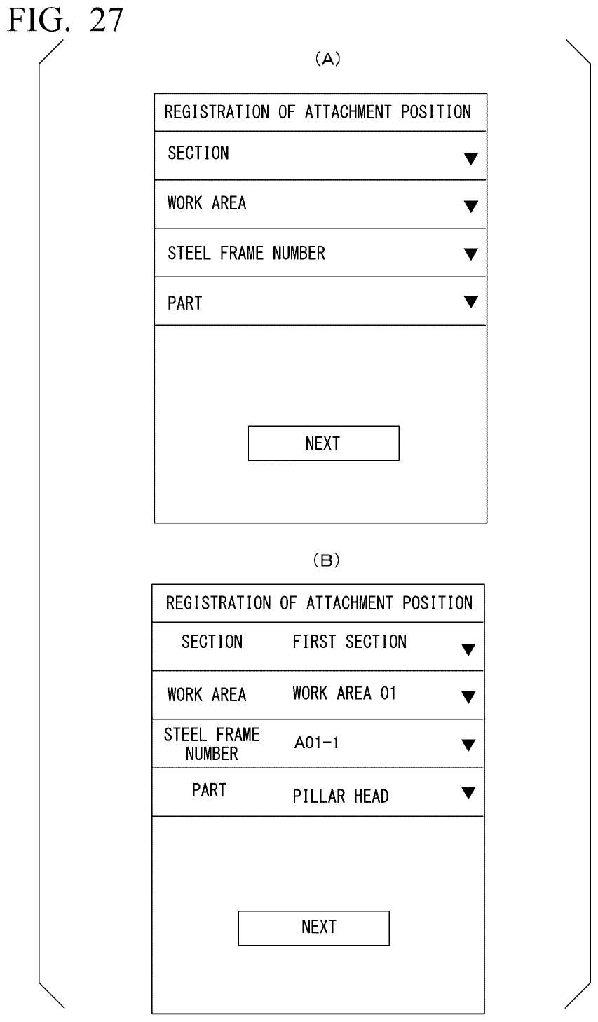

In the following Step S608, the registration screen for the attachment position information of the sensor device is displayed in the display screen. FIG. 27(A) shows an example of this registration screen. This registration screen of FIG. 27(A) displays the button “NEXT” together with the selection screen for the pull-down menu of various kinds of items which will be described subsequently.

In FIG. 27(A), if the mark “▾” on the right side of the item “SECTION” is tapped, for example, the pull-down menu of “SECTION” in which choices for the section number such as the first section, the second section, and the third section are enumerated opens. If the mark “▾” on the right side of the item “WORK AREA” is tapped, for example, the pull-down menu of “WORK AREA” in which choices for the work area number such as the work area 01 and the work area 02 are enumerated opens. If the mark “▾” on the right side of the item “STEEL FRAME NUMBER” is tapped, the pull-down menu of “STEEL FRAME NUMBER” in which choices for a plurality of steel frame numbers are enumerated opens. If the mark “▾” on the right side of the item “PART” is tapped, the pull-down menu of “PART” in which choices for the attachment part (position) such as the pillar head, the middle part, and the pillar leg of the sensor device in the pillar (steel frame) are enumerated opens. Here, the positions of the pillar head, the middle part, and the pillar leg respectively correspond to the positions of the three marks M described above.

As is clear from the foregoing description, since the selection screen of the pull-down menu of the items includes the items related to identification of the position of the pillar, and the items related to identification of the position on the pillar, these may be constituted in a hierarchical pull-down menu.

FIG. 27(B) shows an example of a screen after selection when a worker has opened all the pull-down menus and made necessary selections.

As is clear from the foregoing description, an input with respect to the registration screen is performed simply through selection work.

Returning to FIG. 26, in Steps S610 and S612, the attachment position information input through selection of a worker is sequentially taken and stored in the memory (RAM) until the button “NEXT” is tapped (inputting ends). Further, if the worker ends necessary selection work with respect to the foregoing registration screen and taps the button “NEXT”, the judgment in Step S612 becomes positive, and the processing proceeds to Step S614.

In Step S614, the sensor number corresponding to the QR code Cₚ taken in Step S606 and the attachment position information taken in Step S610 are associated (linked) as one piece of data, and it is transmitted to the server 12 via the network 13. Transmission of data with respect to the server 12 is performed after communication with the server 12 is established in a predetermined procedure.

In the following Step S616, after the continuation button and the end button are displayed in the display screen, the processing waits for the continuation button or the end button to be tapped in Steps S618 and S620. Further, when the continuation button is tapped by a worker and continuation is selected, the judgment in Step S618 becomes positive, and the processing returns to Step S602. Thereafter, without having the continuation button being tapped, the processing of the loop of Steps S602 to S618 (including judgment) is repeated until the end button is tapped. Meanwhile, if a worker ends the processing with respect to the planned number of sensor devices and the end button is tapped without tapping the continuation button, the judgment in Step S620 becomes positive, and a series of processing ends.

In this way, when a worker repeatedly performs operation according to the instruction contents displayed on the screen of the mobile terminal 16 for a plurality of, for example, three sensor devices 18₁, 18₂, and 18₃, the sensor number of each of the sensor devices 18₁, 18₂, and 18₃ is associated with the attachment position of the sensor device by the mobile terminal 16 (terminal device), and the associated data of the sensor number and the attachment position (information of the association results) is sent to the server 12.

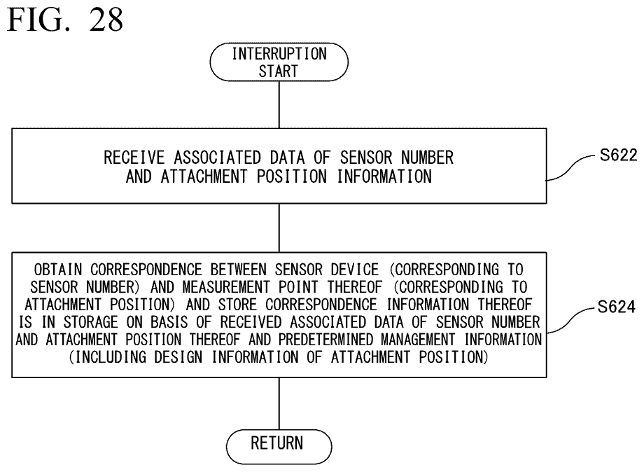

FIG. 28 shows a flowchart of a routine of interruption processing executed by the CPU of the server 12 corresponding to the foregoing Step S5. This routine of interruption processing starts when a response to a permission request for communication is returned from the mobile terminal 16 while the communication described above is being established. First, in Step S622, the associated data (information of the association results) of the sensor number and the attachment position thereof sent from the mobile terminal 16 is received.

In the following Step S624, on the basis of the received associated data of the sensor number and the attachment position thereof and the predetermined management information (including the design information of the attachment position), a correspondence between the sensor device (corresponding to the sensor number) and the measurement point thereof (corresponding to the attachment position) is obtained, and the correspondence information thereof is stored in the storage. Thereafter, the processing returns to a main routine.

Actually, the processing according to the flowcharts in FIG. 25 or FIGS. 26 and 28 is performed for all the sensor devices 18ₚ attached to all the pillars 100ⱼ.

As is clear from the description so far, in the present fourth embodiment, an information acquisition system is constituted to include the mobile terminal 16 and the server 12 connected the plurality of sensor devices 18ₚ via the network 13.

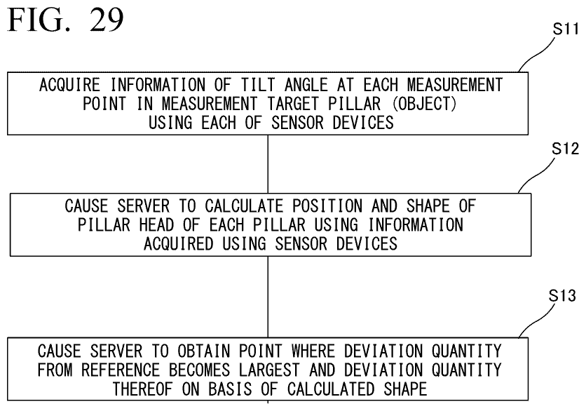

Next, a flow of a shape acquisition method according to the present embodiment will be described on the basis of the flowchart in FIG. 29. The sensor devices 18ₚ is attached to a pillar selected as a measurement target in many pillars constituting the steel frame building 110 shown in FIG. 3. Hereinafter, a case in which three sensor devices 18ₚ are attached to the first surface of each of the pillar 1003 similarly to the pillar 100₁ shown in FIG. 4 will be described as an example.

For the three sensor devices attached to each of a plurality of pillars 100ⱼ which have been delivered to places in the vicinity of each of the erection positions within a construction site, information related to the correspondence between the sensor number and the measurement position is acquired as described above. Thereafter, each of the pillars 100ⱼ is erected in a direction in which one end (the right end in FIG. 24(B)) in the longitudinal direction becomes the pillar head. Therefore, after erection, for example, in the pillar 100₁, the three sensor devices 18₁ to 18₃ are disposed side by side upward from below (refer to FIG. 4) on the first surface (measurement surface).

Here, it is assumed that each of the sensor devices 18ₚ is calibrated in advance such that no measurement error occurs. In addition, each of the sensor devices 18ₚ is subjected to necessary setting in advance to be able to perform communication via the network 13 through communication lines (wireless LAN). Therefore, the sensor devices 18ₚ are in a standby state in which they can perform measurement at any time.

First, information of the tilt angle (tilt information) at each of the measurement points (measuring points) in the measurement target pillar 100ⱼ is acquired using each of the sensor devices 18ₚ (Step S11 in FIG. 29).

If acquisition of information of the tilt angle at each of the measurement points in the measurement target pillar 100ⱼ (that is, the pillar 100ⱼ as an object) ends, the server 12 calculates the position and the shape of the pillar head of each of the measurement target pillars using the acquired information of the tilt angle (Step S12 in FIG. 29). In the present embodiment, it is assumed that the two-dimensional shape (shape within the XZ plane) of the first surface to which the sensor devices are attached is calculated as the shape of the pillar.

If calculation of the shape of the pillar ends, the server 12 obtains a deviation quantity of the pillar head with respect to the reference set in advance (refer to the Z axis in FIG. 6), the point where the deviation quantity (corresponding to the deflection amount of the pillar) from the reference becomes the largest, and the deviation quantity thereof on the basis of the calculated shape (Step S13 in FIG. 29).

In the present embodiment, the foregoing Steps S11 to S13 are performed by the shape acquisition system 10A. Therefore, hereinafter, operation of each constituent part of the shape acquisition system 10A will be described.

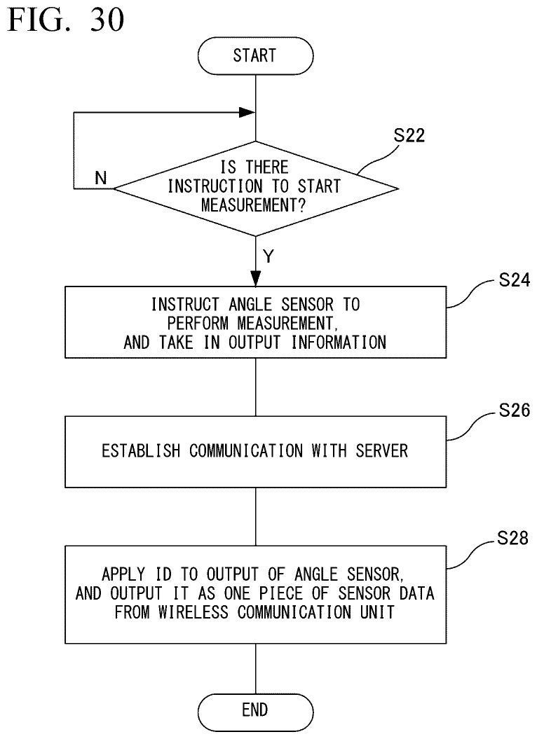

First, operation of each of the sensor devices used in Step S11 will be described on the basis of the flowchart in FIG. 30. This flowchart shows a processing algorithm stipulated by a program which is executed by the CPU of the controlling microcomputer 182. It is assumed that the processing algorithm shown in the flowchart in FIG. 30 starts, for example, when the power sources of the sensor devices 18ₚ are turned on. The power sources are turned on (power source switches (for example, software switches) built into the sensor devices are switched to the ON state) by a remote operation from the outside (for example, the server 12, the work site side computer 14, the mobile terminal 16, or the like).

First, in Step S22, the processing waits for an instruction to start measurement to be input. An instruction to start measurement is performed by the work site side computer 14, the mobile terminal 16, or the server 12 via the network 13. When measurement is instructed to start via a device other than the server 12, the server 12 is notified of this.

Further, if an instruction to start measurement is input, the processing proceeds to Step S24. In Step S24, the angle sensor 181 is instructed to perform measurement, and information (output information) of the tilt angle (at least one axis out of a maximum of three axes) to be measured by the angle sensor 181 is taken.

In the following Step S26, after communication with the server 12 is established, the processing proceeds to Step S28. The sensor number is applied to the taken output information as an identification sign (ID) and is transmitted to the server 12 as one piece of data. Here, the sensor number which has been stored in advance in the memory device when the QR code Cₚ is written using the reader/writer terminal conforming to the communication standard such as NFC in the manufacturing stage is used as an ID. Naturally, this sensor number is the same number as the number stored in the QR code Cₚ unique to the sensor device.

If the processing of Step S28 ends, the processing ends. Accordingly, the sensor devices 18ₚ is in a standby state until a next instruction to start measurement is input.

The processing of the foregoing Steps S22 to S28 is performed for all the sensor devices 18ₚ.

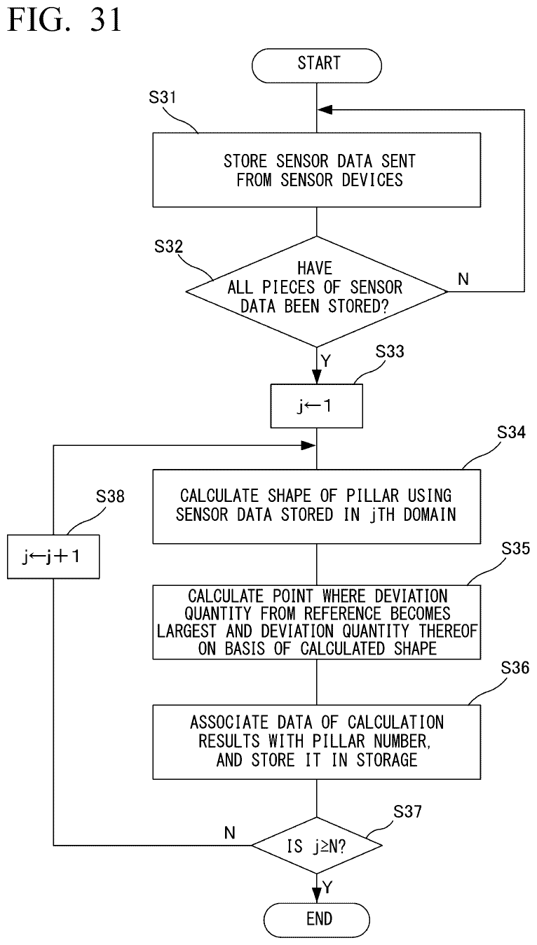

Next, the processing of the server 12 in Steps S12 and S13 will be described on the basis of the flowchart in FIG. 31. FIG. 31 is a flowchart showing a measurement processing algorithm according to a measurement processing program which is executed by the CPU of the server 12. This measurement processing algorithm starts when measurement starting conditions using the sensor devices 18ₚ are satisfied. The measurement starting conditions are satisfied when a notification of starting measurement is received from the work site side computer 14 (or the mobile terminal 16), or when the server 12 instructs at least one of the sensor devices to start measurement.

First, in the loop of Steps S31 and S32, the sensor data sent from the sensor devices 18ₚ is sequentially stored in a predetermined storage domain of the RAM. When a plurality of pieces of sensor data are sent at the same time, the sensor data is concurrently stored in the predetermined storage domain of the RAM through time sharing processing in the server 12. Here, stored data is stored in the storage domain configured for each of the pillars 100ⱼ based on the correspondence between the sensor number and the measurement point.

Further, if taking data from all the sensor devices 18ₚ ends, the processing proceeds to Step S33.

In Step S33, a counter (count value j) indicating a number of the storage domain configured for each of the pillars 100ⱼ (shape measurement target) is initialized (j←1).

In the following Step S34, using the sensor data at a predetermined number of (here, three locations) measurement points stored in a jth (here, first) storage domain, the shape (information) of the pillar 100ⱼ (here, the pillar 100ᵢ) is calculated. For example, the shape calculation method which has been described with reference to FIG. 6 in the first embodiment described above can be used for calculation of the shape of the pillar.

In the following Step S35, the deviation quantity of the pillar head with respect to the reference (Z axis), the point where the deviation quantity from the reference becomes the largest, and the deviation quantity thereof (corresponding to the largest deflection amount of the pillar) are obtained for the pillar 100ⱼ (here, the pillar 100₁) on the basis of the calculated shape.

Further, in the following Step S36, the obtained data (the shape, the deviation quantity of the pillar head, the point of the largest deviation quantity, and data of the deviation quantity) is associated with the pillar number j and is stored in the storage (HDD or the like), and the processing proceeds to Step S37.

In Step S37, it is confirmed whether or not measurement processing has ended by judging whether or not the count value j has reached a total number N of the measurement target pillars for all the measurement target pillars 100ⱼ. Here, since it is in a stage in which the processing has ended for only the first pillar 100₁, the judgment in Step S37 becomes negative. The processing shifts to Step S38 and the count value j is incremented by 1 (i←j+1). Further, the processing returns to Step S34, and thereafter, the processing of the loop of Steps S34 to S38 (including judgment) is repeated until the judgment in Step S37 becomes positive. Accordingly, measurement processing is sequentially performed for the pillars 100ⱼ (j=2 to N) from the second pillar to the Nth pillar.

Meanwhile, if the judgment in Step S37 becomes positive, a series of processing ends.

In the description so far, a case in which three sensor devices 18ₚ are disposed in the upward-downward direction on the measurement surface has been described. However, it is also considered that the sensor devices 18ₚ are two-dimensionally disposed on the measurement surface. Particularly, when the measurement surface of an object is a three-dimensionally curved surface, the sensor devices need to be disposed two-dimensionally on the measurement surface. However, since the sensor devices 18ₚ actually output the tilt angles of the normal vectors (three-dimensional tilt angles) on the measurement surface Ws, the shape of the measurement surface of an object (surface shape) can also be derived from the measurement point coordinates and the measurement value of the normal vector. For example, the shape may be calculated by obtaining the surface slope of each of the measurement points and the height of each of the measurement points with respect to the reference surface (the deviation quantity from the reference surface) from the first-order integral thereof, or the shape of an object may be obtained on the basis of a function obtained by changing the function subjected to fitting to data of a tilt distribution obtained from a plurality of pieces of data regarding the same object obtained through measurement into an integral system. For example, a function such as a differential Zernike can be used as the fitting function. The shape may be calculated using coordinates of a finite number of discrete measurement points on the measurement surface of an object and actually measured values of the normal vector by optimizing the order and the coefficients of an approximated surface indicated by a Fourier series expansion, for example, such that errors at the respective measurement points are minimized. Further, in the shape acquisition method according to the present embodiment, various methods using various functions can be used as long as the shape can be calculated using information of the tilt angles at a plurality of measurement points (tilt information).

The measurement processing algorithm in FIG. 31 is performed every timing when the sensor data of the pillar (object) is taken. That is, every timing when the sensor data is taken for each of all the measurement target pillars (objects), calculation of the shape, calculation of the deviation quantity of the pillar head and the largest deviation quantity (corresponding to the largest deflection amount), and storing of the calculation results associated with the pillar number (the number of the object) are repeatedly performed. Hence, the domain associated with the number of the object (pillar number) may be repeatedly overwritten (that is, stored contents may be updated) when calculation results are stored by configuring a rewritable data table associated with the number of the object (pillar number) in advance in a predetermined domain of the storage. Moreover, the server 12 may create or update the data table as table data in which the latest information stored in the storage is associated with the design data, and it may be transmitted to the work site side computer 14 via the network 13 every time it is created or updated. In this case, the work site side computer 14 can create and update the database stored in the storage device such as the RAM or the HDD, for example, using the sent table data.

In this case, change in shape of the object (pillar) over time or the like can also be monitored on the basis of the created and updated database. In addition, stress occurring in the object (pillar) can also be calculated or the like by calculating the strength on the basis of the shape.

When monitoring change over time or the like for a long period, it becomes necessary to supply power (power feeding) to each of the sensor devices. However, regarding countermeasures in this case, power feeding using a MEMS vibration generator, wireless power feeding (non-contact power feeding) of transmitting power utilizing an induced magnetic flux generated between the power transmission side and the power reception side of an electromagnetic induction method, solar power generation, wired LAN power feeding using a LAN cable, or the like is considered.

In the steel frame building 110, as shown in FIG. 4, the sensor devices 18ₚ are disposed at the same height positions on two surfaces extending in the longitudinal direction of the pillar 100ⱼ and orthogonal to each other (the first surface orthogonal to the X axis and the second surface orthogonal to the Y axis). Specifically, the sensor devices 18₁, 18₂, and 18₃ are disposed on the first surface, and the sensor devices 18₄, 18₅, and 18₆ are disposed on the second surface. In this case, the shape of the first surface may be obtained on the basis of outputs of the sensor devices 18₁, 18₂, and 18₃ and information of the shape of the second surface may be obtained on the basis of outputs of the sensor devices 18₄, 18₅, and 18₆ respectively by the measurement processing algorithm (refer to FIG. 31) according to the measurement processing program described above.

Here, as shown in FIG. 4, when the sensor devices are attached to two surfaces extending in the longitudinal direction of the pillar 100 and orthogonal to each other, the pull-down menu of the item “AZIMUTH” including choices such as south and north may be added to the registration screen for the attachment position information as shown in FIG. 27(A).

As described above, according to the information acquisition method of the present fourth embodiment, when a worker at a construction site simply reads the QR codes Cₚ displayed in the sensor devices 18ₚ attached to the pillar 1003 in accordance with display of the screen of the mobile terminal 16 at the work site and selects each of the items in the registration screen for the attachment position information (that is, inputs the attachment position information), information related to the correspondence between the sensor device having the sensor number corresponding to the QR code thereof and the measurement point thereof is automatically acquired by the server 12 and is stored in the storage every time it is performed. Therefore, information related to the correspondence between the plurality of sensor devices and the measurement positions thereof is simply acquired. In addition, since the registration screen described above is configured to have the pull-down menu for each of the items, necessary information can be input by simply opening the pull-down menu and selecting a corresponding choice. Accordingly, compared to when characters (texts) or the like are input via a keyboard or the like, inputting is facilitated and an input error can also be expected to be reduced.

In addition, according to the information acquisition method of the present fourth embodiment, it is sufficient for each of the sensor devices to output the sensor data including only the sensor number as an ID, and there is no need for the ID to include the correspondence between the pillar number and the attachment position in addition to the sensor number. For this reason, it is sufficient to simply write the sensor number used as an ID in the data form such as the QR code in the memory domain inside the sensor device immediately after manufacturing. Therefore, no troublesome work is required concomitantly with it when the sensor device is attached to the pillar.

In addition, according to the shape acquisition method of the present fourth embodiment, a part of the object, for example, the shape of the surface to which the sensor device is attached (measurement surface), and ultimately the shape of the pillar and the largest deviation quantity and the like from the reference surface in the entire measurement area can be acquired by performing predetermined computation using the information of the tilt angles (tilt information) at a plurality of measurement points in the pillar acquired by the plurality of sensor devices attached to the pillar. Accordingly, the shape of the pillar can be obtained without using light, a three-dimensional measurement instrument or the like using light is no longer necessary, and even if there is an obstacle or the like, an influence thereof is not received.

In the foregoing fourth embodiment, a case in which when a predetermined number of sensor devices attached to a pillar at a construction site are associated with the attachment positions, after the QR codes displayed in the sensor devices are read using the mobile terminal, the information of the attachment positions is input to the mobile terminal and the sensor devices (sensor numbers) and the attachment positions are associated using (via) the mobile terminal has been described. However, it is not limited to this, and the sensor devices (sensor numbers) and the attachment positions may be associated via the mobile terminal in a procedure as in a modification example which will be described subsequently.

### Modification Examples

This modification example is related to a processing algorithm of the mobile terminal 16 when the sensor devices (sensor numbers) and the attachment positions are associated by switching the order of Step S1 and Step S2 in the flowchart in FIG. 25 described above.

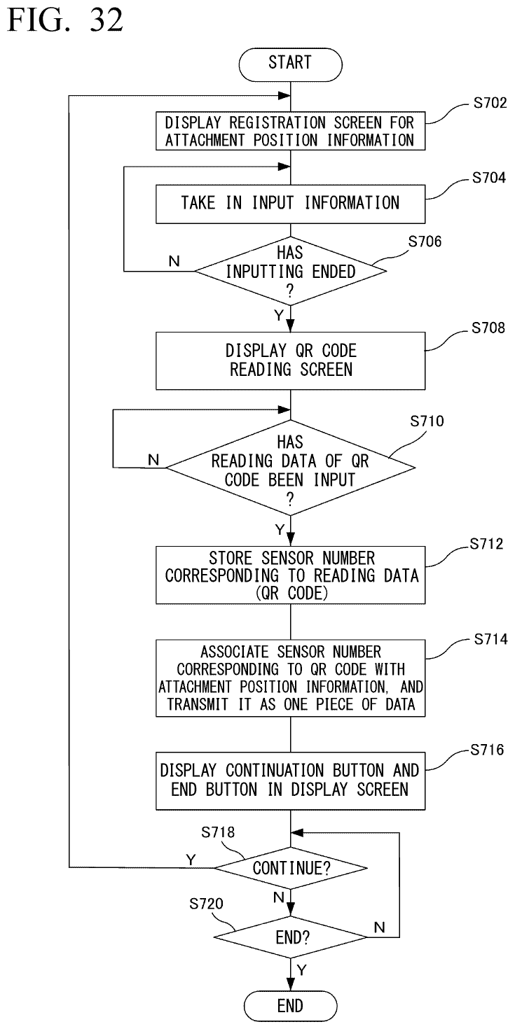

FIG. 32 shows a flowchart corresponding to a processing algorithm of the CPU of the mobile terminal 16 according to the modification example. An application (program) corresponding to this processing algorithm is installed in advance in the mobile terminal 16.

The processing algorithm in FIG. 32 starts with activation of the foregoing application.

First, in Step S702, the registration screen for the attachment position information of the sensor device (FIG. 27(A) shows an example of this screen) is displayed on the screen of the display. Details of the display contents of the registration screen in FIG. 27(A) have been described earlier.

In the loop of the following Steps S704 and S706, until the button “NEXT” is tapped, the information selected (input) by a worker from the pull-down menu of each of the items in the registration screen is sequentially taken and stored in the memory (RAM). Further, if the worker inputs all the necessary information and the button “NEXT” is tapped, the judgment in Step S706 becomes positive, and the processing proceeds to Step S708.

In Step S708, after the QR code reading screen is displayed on the screen of the display, in the following Step S710, the processing waits for the reading data of the QR code to be input. Further, the worker reads the QR code Cₚ (here, C₁) displayed on the display panel of the sensor device 18ₚ (here, the first sensor device 18₁) using the camera of the mobile terminal 16, and if the reading data is input, the processing proceeds to Step S712. The sensor number corresponding to the QR code Cₚ included in the reading data is stored in the memory (RAM).

In the following Step S714, the attachment position information taken in Step S704 and the sensor number corresponding to the QR code Cₚ stored in Step S712 are associated as one piece of data, and it is transmitted to the server 12 via the network 13. Transmission of data with respect to the server 12 is performed after communication with the server 12 is established in a predetermined procedure.

In the following Step S716, after the continuation button and the end button are displayed on the screen of the display, the processing waits for the continuation button or the end button to be tapped in Steps S718 and S720. Further, when the continuation button is tapped by a worker and continuation is selected, the judgment in Step S718 becomes positive, and the processing returns to Step S702. Thereafter, without having the continuation button being tapped, the processing of the loop of Steps S702 to S718 (including judgment) is repeated until the end button is tapped. Meanwhile, if a worker ends the processing with respect to the planned number of sensor devices and the end button is tapped without tapping the continuation button, the judgment in Step S720 becomes positive, and a series of processing ends.

In this way, when a worker repeatedly performs operation according to the instruction contents displayed on the screen of the mobile terminal 16 for a plurality of, for example, three sensor devices 18₁, 18₂, and 18₃, the sensor number of each of the sensor devices 18₁, 18₂, and 18₃ is associated with the attachment position of the sensor device by the mobile terminal 16, and the associated data of the sensor number and the attachment position (information of the association results) is sent to the server 12.

In the server 12, every time there is a permission request for communication from the mobile terminal 16 when communication described above is established, the processing of the routine of interruption processing described above (FIG. 28) is performed.

Actually, the processing according to the flowcharts of FIGS. 32 and 28 is performed for all the sensor devices 18ₚ attached to all the pillars 100ⱼ.

Even by the modification example described above, effects equivalent to those of the foregoing fourth embodiment can be obtained.

In the foregoing fourth embodiment and the modification example thereof, a case in which the QR codes of the sensor devices attached to the pillar are read before erection of the pillar at a construction site has been described. However, it is not limited to this, and the QR codes of the sensor devices attached to the pillar can also be read after erection of the pillar.

### Fifth Embodiment

Next, a fifth embodiment will be described. In the present fifth embodiment, the constitution and the like of the shape acquisition system 10A are similar to those of the fourth embodiment, but the place where the mobile terminal 16 playing a role of an acquisition device is used differs from that of the foregoing fourth embodiment. That is, in the fourth embodiment, after a pillar is delivered to a construction site, a worker at a work site uses the mobile terminal 16 in a stage in which the sensor devices are attached to the pillar at the construction site. In contrast, in the present fifth embodiment, before a plurality of sensor devices are attached to a pillar, a worker within a shipping factory of the sensor devices, for example, uses the mobile terminal 16. Due to the difference in place of use and user of this mobile terminal 16, in the present fifth embodiment, the information acquisition method and the processing algorithm of the mobile terminal 16 differ from those of the fourth embodiment described above. Hereinafter, focusing on this difference, the present fifth embodiment will be further described.

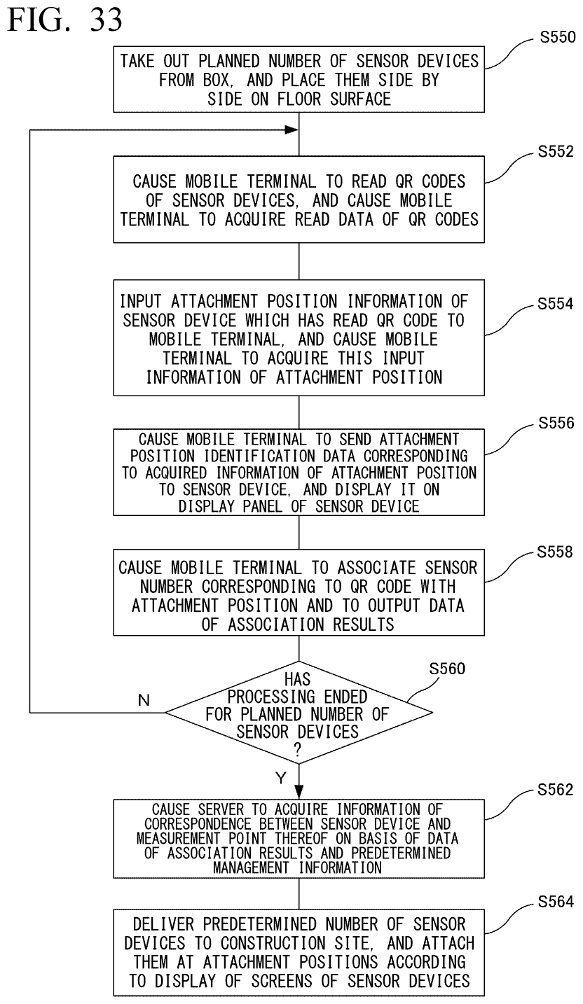

FIG. 33 shows a flowchart of a flow of processing of the information acquisition method according to the present fifth embodiment.

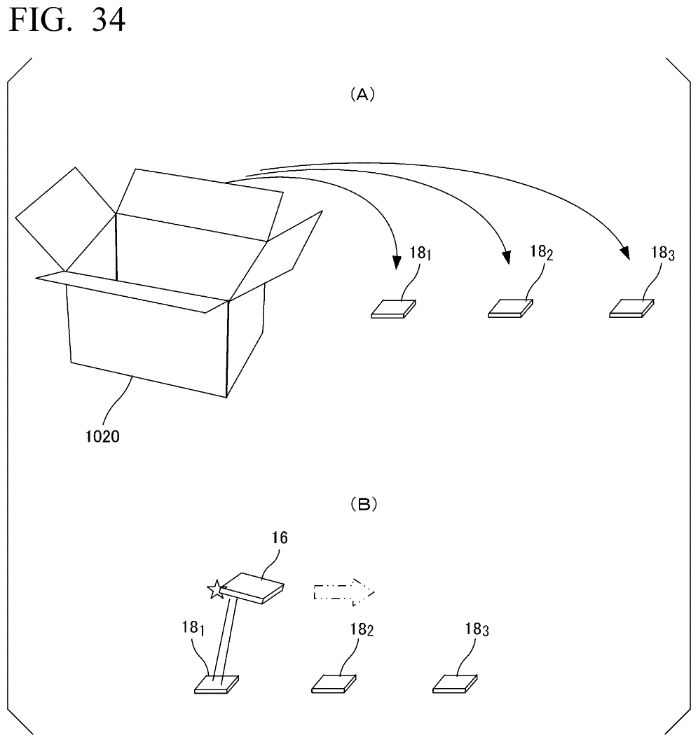

First, as shown in the (A) part of FIG. 34, a planned number of (plurality of) sensor devices 18ₚ are taken out from a box 1020 within a shipping factory of the sensor devices and are placed side by side on a floor surface (or a table which is not shown) (Step S550 in FIG. 33). For the sake of convenience, the (A) part and the (B) part of FIG. 34 show the three sensor devices 18₁, 18₂, and 18₃ of the plurality of sensor devices 18ₚ. The processing in Step S50 may be performed by a worker within a shipping factory or may be performed by a robot. Here, before being packed in the box 1020, each of the sensor devices 18ₚ performs writing of information using a reader/writer terminal or the like conforming to the communication standard such as NFC, the unique sensor numbers and the QR codes Cₚ storing the sensor numbers are stored in the user memory domain (or the memory domain in the HF band IC) of the memory device of the controlling microcomputer 18₂, and the QR codes Cₚ are displayed on the display panel of the electronic paper 187A together with the sensor numbers.

Next, as shown in FIG. 34 (B), reading of the QR codes Cₚ displayed in the sensor devices 18ₚ is performed by the mobile terminal 16, and the mobile terminal 16 acquires the reading data of the QR codes (Step S552 in FIG. 33). Here, reading of the QR codes Cₚ may be performed by a worker within a shipping factory or may be performed by a robot.

Next, the information of the attachment positions of the sensor devices 18ₚ is input to the mobile terminal 16, and the mobile terminal 16 acquires the input information of the attachment positions (Step S554 in FIG. 33). Here, the information of the attachment positions is input by a worker of a shipping factory using the registration screen for the attachment position information described above displayed in the display screen of the mobile terminal 16. As described above, before the pillar 100₁ is delivered to a construction site, the server 12 has acquired data and the like of design drawings of the steel frame building 110, and the attachment positions are set for each pillar such that the measurement points by the sensor devices 18ₚ match the attachment positions thereof on the basis of the data of this design drawings. However, at the point of time before the pillar 100ᵢ is delivered to a construction site, the server 12 does not recognize the correspondence between the sensor devices, and the attachment targets and the attachment positions thereof.

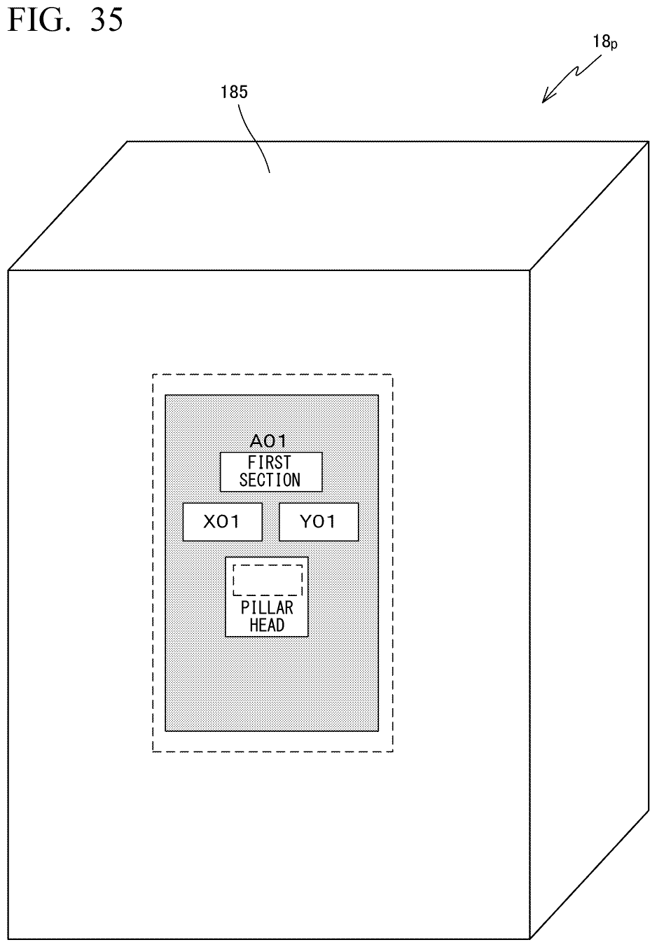

Next, the mobile terminal 16 converts the acquired information of the attachment positions into corresponding attachment position identification data, sends it to the sensor devices 18ₚ, and displays the attachment position identification data on the display panels (Step S556 in FIG. 33). Accordingly, on the display panels of the sensor devices 18ₚ, as shown in FIG. 35, the attachment position identification data (position identification data (the section number, the X position number, and the Y position number) identifying the position of the pillar and data of the part on the pillar) is displayed together with the sensor number. Conversion from the foregoing information of the attachment positions into the attachment position identification data by the mobile terminal 16 will be further described below. A center line sign in the X direction may be used in place of the X position number, and a center line sign in the direction may be used in place of the Y position number.

Next, the mobile terminal 16 associates the sensor numbers (the numbers unique to the sensor devices) obtained by character-converting dots included in the acquired (read) QR codes with the acquired information of the attachment positions and outputs data of the association results (Step S558 in FIG. 33).

Further, it is judged whether or not processing has ended for the planned number of sensor devices (Step S560 in FIG. 33). When the processing of the planned number of sensor devices has not ended, the judgment thereof becomes negative, and the processing returns to Step S552. The processing of the foregoing Steps S552 to S558 is performed for other sensor devices. Meanwhile, if the processing of the planned number of sensor devices ends, the judgment in Step S560 becomes positive, and the processing shifts to Step S562.

In Step 562, the server 12 acquires the correspondence information between the sensor devices and the measurement points thereof on the basis of data of the foregoing association results and predetermined management information (including the design information of the attachment position).

Next, after being delivered to a construction site, the predetermined number of sensor devices are attached at the attachment positions identified by the attachment position identification data displayed in the display panel of each of the sensor devices. As described above, the attachment position identification data displayed in the display panel includes the position identification data (the section number, the X position, and the Y position) identifying the position of the pillar and data of the part on the pillar. Therefore, each of the sensor devices is attached to the designated part (attachment position) in a pillar to be erected at the identified position.

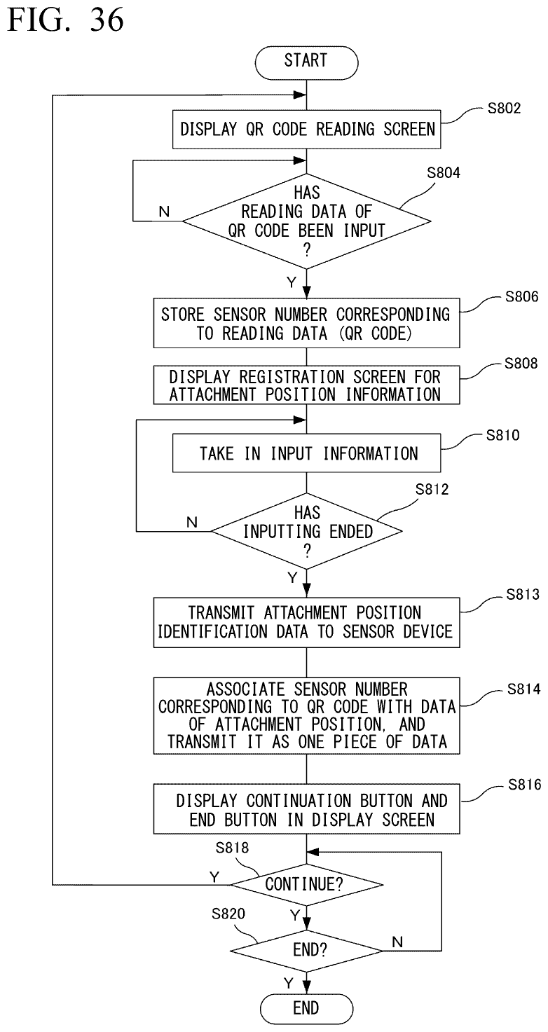

FIG. 36 shows a flowchart corresponding to a processing algorithm of the CPU of the mobile terminal 16 corresponding to the foregoing steps S552 to S560. An application (program) corresponding to this processing algorithm is installed in advance in the mobile terminal 16.

The flowchart (processing algorithm) in FIG. 36 starts with activation of the foregoing application.

First, in Step S802, the QR code reading screen is displayed on the screen of the display.

In the following Step S804, the processing waits for reading data of the QR code to be input. Further, if a worker reads the QR code Cₚ displayed on the display panel of the sensor device 18ₚ using the camera of the mobile terminal 16 and the reading data thereof is input, the processing proceeds to Step S806, and the sensor number corresponding to the QR code Cₚ included in the reading data (the sensor number obtained by character-converting dots included in the QR code) is stored in the memory (RAM).

In the following Step S808, the registration screen for the attachment position information is displayed on the screen of the display. FIG. 27(A) shows an example of this registration screen. The registration screen of FIG. 27(A) has been described earlier.

Next, in Steps S810 and S812, until the button “NEXT” (refer to FIG. 27(A)) is tapped, the information input by a worker is taken and stored in the memory (RAM). Further, if the worker taps the button “NEXT” after inputting ends, the judgment in Step S812 becomes positive, and the processing proceeds to Step S813.

In Step S813, data to be displayed in the display panel of the sensor device (attachment position identification data) is transmitted by performing near field wireless communication (NFC) with the sensor device 18ₚ. This attachment position identification data is obtained as follows. The CPU of the mobile terminal 16 has a data table including the work area, the steel frame number, and the identification information (the X position number and the Y position number) of the position of the pillar corresponding to this information. Therefore, if the choices of the work area and the pillar number are selected in each of the pull-down menus of the registration screen, the selected choices of the work area and the pillar number are converted into the corresponding identification information of the position of the pillar (the X position number and the Y position number), and these X position number and Y position number are put together with the selected choices of the section and the part as a piece of attachment position identification data. That is, in this way, conversion of the information of the attachment positions described above into the attachment position identification data is performed.

The attachment position identification data is displayed on the display panel of the electronic paper 187A by the CPU of the sensor device 18ₚ which has received the foregoing data.

In the following Step S814, the sensor number corresponding to the QR code Cₚ stored in Step S806 and the information of the attachment positions taken in Step S810 are associated as one piece of data and transmitted to the server 12 via the network 13. Transmission of data with respect to the server 12 is performed after communication with the server 12 is established in a predetermined procedure.

In the following Step S816, after the continuation button and the end button are displayed on the display screen, the processing waits for the continuation button or the end button to be tapped in Steps S818 and S820. Further, when the continuation button is tapped by a worker and continuation is selected, the judgment in Step S818 becomes positive, and the processing returns to Step S802. Thereafter, without having the continuation button being tapped, the processing of the loop of Steps S802 to S818 (including judgment) is repeated until the end button is tapped. Meanwhile, if a worker ends the processing with respect to the planned number of sensor devices and the end button is tapped without tapping the continuation button, the judgment in Step S820 becomes positive, and a series of processing ends.

Thereafter, a predetermined number of sensor devices are packed in a box again and are delivered to a construction site. After being delivered, each of the sensor devices is attached at a predetermined attachment position of the pillar 100 delivered to a position identified by the attachment position identification data in accordance with the attachment position identification data displayed on the display panel of the electronic paper 187A of the sensor device. After attachment of the sensor devices, erection of the pillar 100 is performed.

On the other hand, when communication is established prior to transmission of data in the foregoing Step S814, the server 12 is triggered by reception of a permission request for communication from the mobile terminal 16, performs processing according to the routine of interruption processing in FIG. 28 described above. The correspondence between the sensor device (corresponding to the sensor number) and the measurement point thereof (corresponding to the attachment position) is obtained, and the correspondence information thereof is stored in the storage.

Even in the present fifth embodiment, as shown in FIG. 16, when the sensor devices are attached to two surfaces extending in the longitudinal direction of the pillar 100 and orthogonal to each other, the pull-down menu of the item “AZIMUTH” including choices such as south and north may be added to the registration screen for the attachment position information as shown in FIG. 27(A), and in response to this, the azimuth (south, north, or the like) can be displayed in the display panel of the sensor device as shown in FIG. 35. For example, regarding display of the azimuth, it may be displayed in a part surrounded by the dotted line in the upper portion of the pillar head in FIG. 35.

In addition, even in the present fifth embodiment, similar to the fourth embodiment described above, the shape acquisition system 10A acquires the shape and the like of the pillar selected as the measurement target of many pillars constituting the steel frame building 110.

As described above, according to the shape acquisition method of the present fifth embodiment and the system for executing this, effects equivalent to those of the fourth embodiment described above can be obtained. In addition to this, according to the information acquisition method and the system of the present fifth embodiment, since the correspondence between the sensor device and the attachment position (ultimately, the measurement point by the sensor device) can be acquired before the pillar 100ⱼ is delivered to a construction site, for example, the database or the like including data of the foregoing correspondence can be established in a stage before the sensor devices are shipped (a stage in a manufacturing factory or a shipping factory). Moreover, since a work load at a construction site can be reduced, it is possible to expect that working hours of a work site worker are further shortened. Naturally, in a stage in which delivery of the pillars to a construction site has ended, the information acquisition method according to the present fifth embodiment may be performed using the foregoing system.

When delivery of the sensor devices 18ₚ to a construction site can be permitted while being attached to the pillar 100ⱼ, the information acquisition method according to the fourth embodiment described above can also be performed before the pillar 100 is delivered to a construction site.

Thus far, regarding a method for acquiring the QR codes Cₚ (codes) individually stored by a plurality of sensor devices 18ₚ from the outside, a case of employing a technique of reading the QR code displayed in the display panel of the sensor device by the camera of the mobile terminal 16 playing a role as an acquisition device has been described. However, the sensor devices 18ₚ of the foregoing fourth and fifth embodiments have the HF band IC and the HF band antenna inside the wireless communication unit 183A, and an NFC smartphone conforming to the NFC communication standard is used as the mobile terminal 16. In this case, the mobile terminal 16 is caused to function as a reader/writer conforming to the NFC communication standard, and the data (including QR codes) stored in the user memory domain (or the memory domain of the HF band IC) of the controlling microcomputer 182 of the sensor devices 18ₚ can be read by the mobile terminal 16. Therefore, a method for reading data (including QR codes) stored in the user memory domain (or the memory domain of the HF band IC) of the controlling microcomputer 182 of the sensor devices 18ₚ through near field communication using the mobile terminal 16 can also be employed as the method for acquiring the QR codes Cₚ (codes) individually stored by a plurality of sensor devices 18 from the outside. In other words, in Steps S1 and S552 described above, instead of reading the QR codes of the sensor devices using the camera of the mobile terminal, the QR codes can be read from the sensor devices through near field communication using a mobile terminal.

The pillar can be managed (absolute value management, change-over-time management) by repeatedly acquiring the shape of the measurement surface of the pillar, the shape of the pillar, the largest deviation quantity, and the like. Particularly, when a state in which the sensor devices remain being attached to the pillar is maintained and the foregoing shape acquisition method is performed using the shape acquisition system 10A according to the foregoing fourth and fifth embodiments, the shape of the measurement surface as well as the shape of the pillar can be automatically acquired, the deviation quantity from the reference in the entire measurement area can be acquired, and the pillar can be managed (absolute value management, change-over-time management). Therefore, according to the shape acquisition system 10A of the foregoing fourth and fifth embodiments, manual surveying work of steel frame construction can be eliminated. Accordingly, a labor shortage can be improved, and the construction period for the steel frame construction can be shortened.

According to the shape acquisition method of the foregoing fourth and fifth embodiments, since the shape of the measurement surface of the steel frame pillar can be acquired before exterior construction starts, adjustment using a jig of an exterior panel can also be performed in a factory.

In addition, in the foregoing fourth and fifth embodiments, the number of sensor devices used is the same as the number of the plurality of measurement points where the tilt angle information is acquired, but the number does not necessarily have to be the same. In this case, the tilt angle information at two or more measurement points may be acquired using one sensor device.

In addition, in the foregoing fourth and fifth embodiments, with a steel frame pillar taken as an object, calculation of the shape thereof, management of the largest deviation quantity (corresponding to the largest deflection amount) utilizing this, and management of change over time have been described. However, the shape acquisition method and the shape acquisition system according to the foregoing fourth and fifth embodiments (which will hereinafter be abbreviated to a method and a system according to the fourth and fifth embodiments) can be naturally applied to management of steel frames other than steel frame pillars (absolute value management, change-over-time management) and can also be applied to other construction process management. In addition, an object (measurement target) is not limited to the foregoing embodiments (a steel frame pillar of a building or the like). Similar to the third embodiment described above, an object need only be a member to which the sensor devices 18ₚ are attached, for example, a member constituting infrastructure, a vehicle, and other moving objects. Specifically, it may be infrastructure other than a building structure such as a building, for example, a bridge, a dam, a tunnel, an express way, a plant (including a tank and the like), or the like, or may be a wind turbine blade for wind power generation, a body, a wing, or a propeller of an aircraft, a vehicle body (particularly a leading car) of a high-speed train (Shinkansen or the like), railroad rails, a ship and a screw thereof, or the like. In addition to this, an object may be a vehicle (an automobile including an F1 car, an aircraft, a railway, a ship, or the like), an underwater vehicle (a submarine, a deep-sea exploration vessel, or the like), a space-related object (a spacecraft, a re-entry vehicle, or the like), a flying object (a rocket, a missile, a satellite, or the like), a power plant (hydroelectric, thermoelectric, natural gas, nuclear, or the like).

Construction process management in which the method and the system according to the foregoing fourth and fifth embodiments can be favorably applied can include piling management (absolute value management, change-over-time management), earth retaining management (change-over-time management), and the like. Here, a pile denotes a structure serving as a foundation during construction, and earth retaining denotes a wall for holding back the surrounding soil and sand when digging a hole to build an underground structure.

The method and the system according to the foregoing fourth and fifth embodiments can also be applied to infrastructure management. For example, they can be favorably applied to the maintenance of a bridge (change-over-time management), management during construction of a bridge (absolute value management), maintenance of a dam wall surface (change-over-time management), maintenance of a tunnel (change-over-time management), plant/gas tank maintenance (change-over-time management), or the like. Furthermore, the method and the system according to each of the foregoing embodiments can also be applied to analysis of various kinds of deformation amounts. For example, they can be favorably applied to analysis of a deformation amount of a bilge (change over time), analysis of a deformation amount of a wind power generation blade (change over time), analysis of a deformation amount of a wing of an unmanned aircraft (change over time), analysis of a deformation amount of railroad rails (change over time), or the like.

When the method and the system according to the foregoing fourth and fifth embodiments are applied to maintenance of a bridge, for example, a plurality of sensor devices are disposed in the bridge, three-dimensional change in shape from an initial state is monitored at all times. For example, when an index of change in shape (for example, the tilt angle, the largest deviation quantity, and the like output by the sensor devices) exceeds a threshold, for example, an alarm is issued from the server 12 to the work site side computer 14. In this way, a manager of the work site side computer 14 can quickly recognize occurrence of abnormality and the location of occurrence, and therefore efficient visual inspection can be realized.

In each of the foregoing embodiments, there is no particular restriction on a manager of the server 12. For example, the server 12 may be under management of a user of the sensor devices of a construction company or the like, or may be under management of a supplying company (a maker, a supplier, or the like) of the sensor devices. In addition, the server may be a cloud. When the server 12 is under management of a supplying company of the sensor devices, the supplying company leases (or rents) the sensor devices to a user and provides optimal information such as the attachment positions of the sensor devices determined on the basis of the purpose of use acquired in advance. The supplying company receives provision of data acquired by the user using the sensor devices on the basis of the information, performs predetermined analysis (including calculation of shape) using the data, and provides information of analysis results to the user. Further, a fee for provision lease (or rental) of the sensor devices and information is received from the user. Such a business method (business model) can also be realized. In this case, instead of provision of analysis and analysis results, application software (application program) for analysis processing may be leased together with the sensor devices.

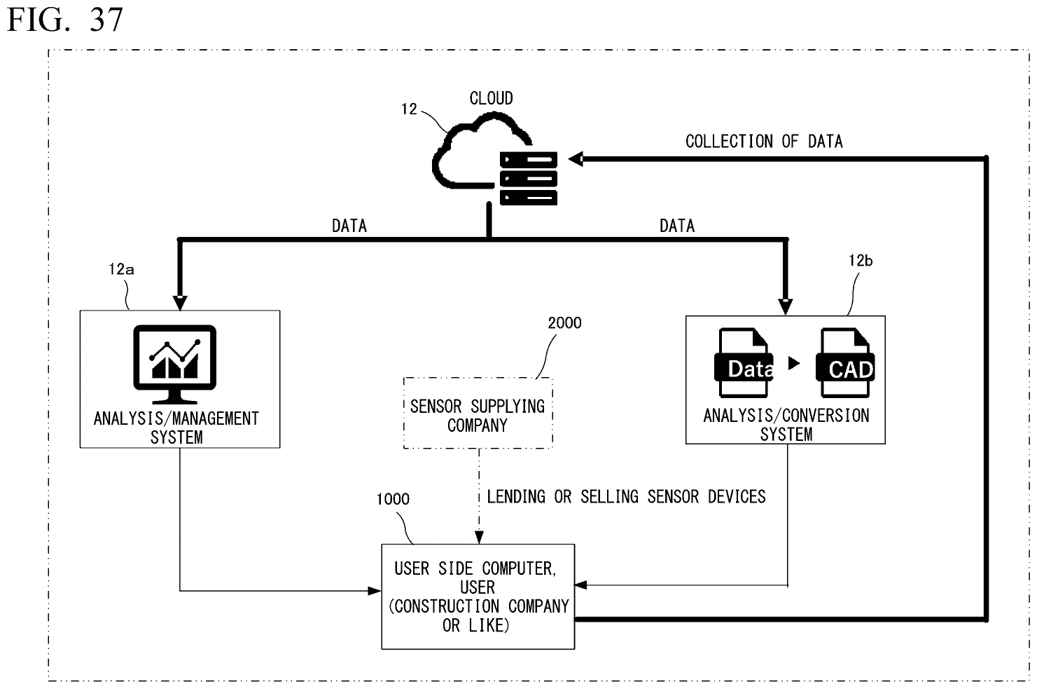

FIG. 37 schematically shows an example of a business model when the server 12 (cloud) is under management of a supplying company of the sensor devices. A supplying company 2000 of the sensor devices sells (transfers) or lends the sensor devices to a user (construction company) 1000. Lending includes rental and leasing.

The supplying company 2000 receives provision of data acquired by the user using the sensor devices via a user accessible computer (which will be referred to as a user side computer) 1000. That is, the server 12 (cloud) collects data via data communication with the user side computer 1000. Collected data includes data of the measurement targets of the sensor devices and the like in addition to the sensor data.

The server 12 sends collected data to an analysis/management system 12a or an analysis/conversion system 12b. Here, the analysis/management system 12a is a system which performs predetermined analysis (including calculation of shape) using the data and creates predetermined management information utilizing the analysis results. For example, the analysis/management system 12a schematically shows the function of the server 12 and the like in the shape acquisition system 10A according to the fourth and fifth embodiments described above or the system 10 according to the first to third embodiments described above.

In addition, the analysis/conversion system 12b is a system which adds conversion utilizing the analysis results of data collected by the server to the database (may be a database for BIM described above) including design information of a measurement object of the sensor devices. As described earlier using FIG. 10, for example, after welding of the steel frame which belongs to one work area of one section has ended, every time approval work described above is performed, in Step S122 described above, data of the pillar head positions of all the steel frames which belong to the work area is linked to the design data of the steel frame and is added to the database. Further, construction drawings for the next process is inevitably created based on the information of the BIM database after this addition. For example, the analysis/conversion system 12b conceptually shows the function of the server 12 in such a case. In the foregoing embodiment, updating of the design data of the steel frame has been described in relation to approval work for erection. However, since updating, changing, and the like of design data (may be CAD data) based on the measurement data (sensor data) measured by the sensor devices can be performed regardless of approval for erection, the analysis/conversion system 12b is a system independent from the analysis/management system 12a.

The server 12, the analysis/management system 12a, and the analysis/conversion system 12b can be realized by the same computer (may be a cloud), but the analysis/management system 12a and the analysis conversion system 12b can also be individually constituted using another computer connected to the server 12 via a network.

When the server 12 collecting data from the user side computer 1000 is under management of the supplying company 2000 of the sensor devices, normally, the analysis/management system 12a and the analysis/conversion system 12b are also under management of the supplying company 2000. Therefore, in this case, information obtained through processing of the analysis/management system 12a or the analysis/conversion system 12b is provided as the fee for utilization of the analysis/management system 12a or the analysis/conversion system 12b. Specifically, a form in which the analysis/management system 12a is provided to a user as an application and the user pays a usage fee to the supplying company is considered. In the case of the analysis conversion system 12b, for example, a form in which it is provided as a construction CAD system and the user pays a usage fee of the system itself is considered.

According to the business model in FIG. 37, a method for utilizing data obtained using the sensor devices is realized. The method includes causing the server 12 to collect data obtained by a user using a sensor device via data communication with a user accessible computer 1000, causing the server 12 to provide the collected data to the analysis/management system 12a or the analysis/conversion system 12b, causing the analysis/management system 12a or the analysis/conversion system 12b to perform predetermined processing using the provided data, and providing information obtained through processing of the analysis/management system 12a or the analysis/conversion system 12b from the analysis/management system 12a or the analysis/conversion system 12b to the user 1000 via the computer.

### REFERENCE SIGNS LIST

10 System
12 Server
13 Network
14 Work site side computer
16 Mobile terminal
18₁ to 18₃ Sensor device
20 Database server
100 Steel frame pillar
110 Steel frame building

1.-50. (canceled)

51. A system used in construction of a structure, comprising:
a plurality of sensor devices attached to a part of a structure as a target object such that tilt angle information of the target object is acquired at each of a plurality of points that are different in position with respect to at least a first direction;
a management device that calculates shape information of the target object based on measurement information of the target object by the plurality of sensor devices, wherein
each of the plurality of sensor devices has an angle sensor, and transmits the measurement information to the management device via a network, and
the management device provides the calculated shape information via the network to a terminal device used in design or construction of the structure.

52. The system according to claim 51, wherein
the shape information is used in the terminal device to design a component of the structure.

53. The system according to claim 52, wherein
the terminal device has a database in which design data for the structure is stored, and
the shape information can be stored in the database as CAD data.

54. The system according to claim 53, wherein
the database is a database for BIM (Building Information Modeling).

55. The system according to claim 52, wherein
the component includes at least one of a steel column and a component used for interior construction and/or exterior construction.

56. The system according to claim 52, wherein
the terminal device includes a manager terminal for the construction, and
the manager terminal can display the shape information so that a manager can check whether construction error of the target object is within a tolerance.

57. The system according to claim 51, wherein
the terminal device includes a manager terminal for the construction, and
the manager terminal can display the shape information so that a manager can check whether construction error of the target object is within a tolerance.

58. The system according to claim 57, wherein
after a work in a target construction area for the structure including the target object, the shape information is displayed on the manager terminal for the check by the manager.

59. The system according to claim 58, wherein
the terminal device includes a worker terminal for a construction worker, and
a request for the check is made via the worker terminal.

60. The system according to claim 51, wherein
each of the plurality of sensor devices measures the tilt angle information with respect to the first direction.

61. The system according to claim 60, wherein
the target object is a steel column that constitutes the structure, and the steel column is installed so as to be substantially parallel to the first direction, which is along a direction of gravity.

62. The system according to claim 61, wherein
the structure includes at least one of a building, a bridge, a tunnel, an express way, a dam, a wind turbine, and a power plant.

63. A method of constructing a structure, the method comprising:
acquiring tilt angle information, by using a plurality of sensor devices, of a target object at each of a plurality of points that are different in position with respect to at least a first direction;
transmitting measurement information of the target object measured by the plurality of sensor devices to a management device via a network;
calculating shape information of the target object based on the measurement information; and
providing the calculated shape information via the network to a terminal device used in design or construction of the structure, wherein
each of the plurality of sensor devices includes an angle sensor.

64. The method according to claim 63, wherein
the shape information is used in the terminal device to design a component of the structure.

65. The method according to claim 64, wherein
the shape information is stored in a database of the terminal device, as CAD data, design data for the structure being stored in the database.

66. The method according to claim 65, wherein
the database is a database for BIM (Building Information Modeling).

67. The method according to claim 64, wherein
the component includes at least one of a steel column and a component used for interior construction and/or exterior construction.

68. The method according to claim 64, wherein
the terminal device includes a manager terminal for the construction, and
the manager terminal can display the shape information so that a manager can check whether construction error of the target object is within a tolerance.

69. The method according to claim 63, wherein
the terminal device includes a manager terminal for the construction, and
the manager terminal can display the shape information so that a manager can check whether construction error of the target object is within a tolerance.

70. The method according to claim 69, wherein
after a work in a target construction area for the structure including the target object, the shape information is displayed on the manager terminal for the check by the manager.

71. The method according to claim 70, wherein
the terminal device includes a worker terminal for a construction worker, and
a request for the check is made via the worker terminal.

72. The method according to claim 63, wherein
each of the plurality of sensor devices measures the tilt angle information with respect to the first direction.

73. The method according to claim 72, wherein
the target object is a steel column that constitutes the structure, and the steel column is installed so as to be substantially parallel to the first direction, which is along a direction of gravity.
